(19) United States
(12) Patent Application Publication
(10) Pub. No.: US 2026/0271740 A1
(43) Pub. Date: Sep. 10, 2026

(54) METHOD FOR MANUFACTURING WIRING SUBSTRATE

(71) Applicant: IBIDEN CO., LTD., Gifu (JP)

(72) Inventors: Jo SUZUKI, Gifu (JP); Hiroyasu NAGATA, Gifu (JP)

(73) Assignee: IBIDEN CO., LTD., Gifu (JP)

(21) Appl. No.: 19/557,279

(22) Filed: Mar. 5, 2026

(30) Foreign Application Priority Data
Mar. 7, 2025 (JP) 2025-036718

(51) Int. Cl. H10W 70/09; H10W 74/01; H10W 70/68; H10W 90/00

(52) U.S. Cl. CPC H10W 70/09; H10W 74/01; H10W 70/682; H10W 90/734

(57) ABSTRACT

A method for manufacturing a wiring substrate includes forming a conductor layer on a surface of a first insulating layer such that the conductor layer includes a conductor pad forming a laser stopper, forming a second insulating layer on the first insulating layer such that the second insulating layer covers the conductor layer, forming an opening in the second insulating layer by irradiation with laser light such that the opening partially exposes the conductor pad, etching the conductor pad such that a recess is formed in an inner wall surface of the second insulating layer in the opening and exposes a surface of a remaining portion of the conductor pad at position recessed from the inner wall surface, cutting the inner wall surface such that a depth of the recess is reduced, positioning a component in the opening formed in the second insulating layer, and filling the opening with resin.

### CROSS-REFERENCE TO RELATED APPLICATIONS

The present application is based upon and claims the benefit of priority to Japanese Patent Application No. 2025-036718, filed March 7, 2025, the entire contents of which are incorporated herein by reference.

### BACKGROUND OF THE INVENTION

### Field of the Invention

The present invention relates to a method for manufacturing a wiring substrate.

### Description of Background Art

Japanese Patent Application Laid-Open Publication No. 2020-184596 describes a method for manufacturing an electronic component-embedded wiring substrate. The entire contents of this publication are incorporated herein by reference.

### SUMMARY OF THE INVENTION

According to one aspect of the present invention, a method for manufacturing a wiring substrate includes forming a conductor layer on a surface of a first insulating layer such that the conductor layer includes a conductor pad forming a laser stopper, forming a second insulating layer on the first insulating layer such that the second insulating layer covers the conductor layer, forming an opening in the second insulating layer by irradiation with laser light such that the opening penetrates through the second insulating layer and partially exposes the conductor pad of the conductor layer, etching the conductor pad of the conductor layer such that a recess is formed in an inner wall surface of the second insulating layer in the opening and exposes a surface of a remaining portion of the conductor pad at a position recessed from the inner wall surface of the second insulating layer in the opening, cutting the inner wall surface of the second insulating layer in the opening such that a depth of the recess formed in the inner wall surface of the second insulating layer is reduced, positioning a component in the opening formed in the second insulating layer such that the component is mounted in the opening formed in the second insulating layer, and filling the opening formed in the second insulating layer with resin such that the resin fills the opening of the second insulating layer in which the component is mounted.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating a method for manufacturing a wiring substrate according to an embodiment of the present invention;

FIG. 2 is an enlarged view of a portion (II) of FIG. 1;

FIG. 3 is a plan view illustrating an interior of an opening in FIG. 2 and a surrounding portion thereof;

FIG. 4A is a cross-sectional view illustrating an example of a method for manufacturing a wiring substrate according an embodiment of the present invention;

FIG. 4B is a cross-sectional view illustrating an example of a method for manufacturing a wiring substrate according an embodiment of the present invention;

FIG. 4C is a cross-sectional view illustrating an example of a method for manufacturing a wiring substrate according an embodiment of the present invention;

FIG. 4D is a cross-sectional view illustrating an example of a method for manufacturing a wiring substrate according an embodiment of the present invention;

FIG. 4E is a cross-sectional view illustrating an example of a method for manufacturing a wiring substrate according an embodiment of the present invention;

FIG. 4F is a cross-sectional view illustrating an example of a method for manufacturing a wiring substrate according an embodiment of the present invention;

FIG. 4G is a cross-sectional view illustrating an example of a method for manufacturing a wiring substrate according an embodiment of the present invention;

FIG. 4H is a cross-sectional view illustrating an example of a method for manufacturing a wiring substrate according an embodiment of the present invention;

FIG. 4I is a cross-sectional view illustrating an example of a method for manufacturing a wiring substrate according an embodiment of the present invention;

FIG. 4J is a cross-sectional view illustrating an example of a method for manufacturing a wiring substrate according an embodiment of the present invention;

FIG. 5 is a cross-sectional view illustrating a first modified example of the method for manufacturing a wiring substrate according to the embodiment of the present invention.

FIG. 6A is a cross-sectional view illustrating a method for manufacturing a wiring substrate according an embodiment of the present invention;

FIG. 6B is a cross-sectional view illustrating a method for manufacturing a wiring substrate according an embodiment of the present invention;

FIG. 6C is a cross-sectional view illustrating a method for manufacturing a wiring substrate according an embodiment of the present invention;

FIG. 6D is a cross-sectional view illustrating a method for manufacturing a wiring substrate according an embodiment of the present invention;

FIG. 7 is a cross-sectional view illustrating a method for manufacturing a wiring substrate according to an embodiment of the present invention;

FIG. 8A is a cross-sectional view illustrating a method for manufacturing a wiring substrate according an embodiment of the present invention;

FIG. 8B is a cross-sectional view illustrating a method for manufacturing a wiring substrate according an embodiment of the present invention;

FIG. 8C is a cross-sectional view illustrating a method for manufacturing a wiring substrate according an embodiment of the present invention; and

FIG. 8D is a cross-sectional view illustrating a method for manufacturing a wiring substrate according an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

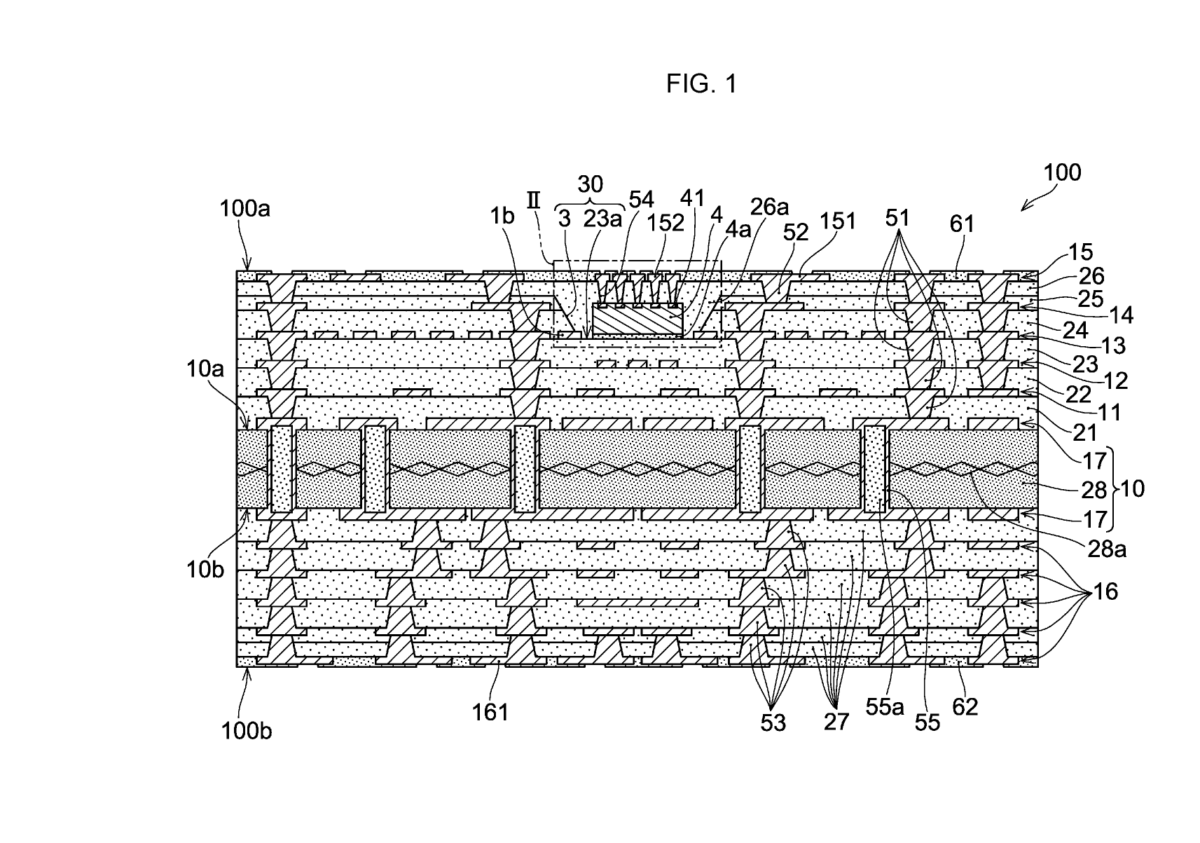

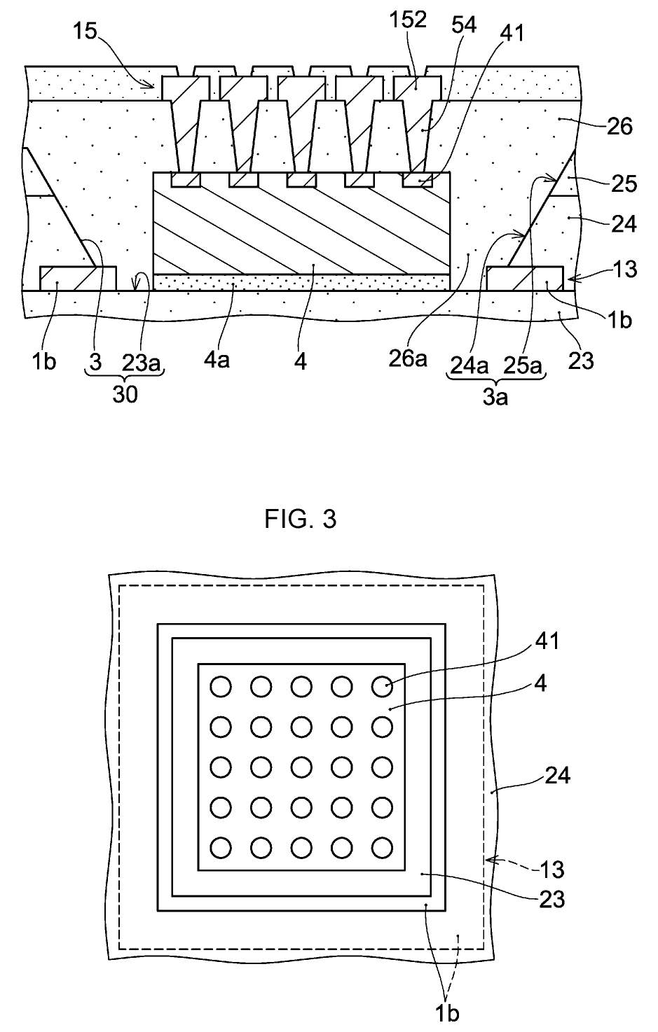

A method for manufacturing a wiring substrate according to an embodiment of the present invention is described with reference to the drawings. FIG. 1 illustrates a cross-sectional view of a wiring substrate 100, which is an example of a wiring substrate manufactured using the method for manufacturing a wiring substrate according to the embodiment (hereinafter, the method for manufacturing a wiring substrate according to the embodiment may also simply be referred to as “the manufacturing method of the embodiment”). FIG. 2 illustrates an enlarged view of a portion (II) of FIG. 1. Further, FIG. 3 illustrates a plan view of an opening 3 and its surroundings illustrated in FIG. 2, with illustration of a portion above a component 4 omitted. The wiring substrate 100 illustrated in FIGS. 1 to 3 is merely an example of a wiring substrate manufactured using the manufacturing method of the embodiment. A laminated structure of a wiring substrate manufactured using the manufacturing method of the embodiment is not limited to a laminated structure of the wiring substrate 100. For example, a wiring substrate manufactured using the manufacturing method of the embodiment may include any number of insulating layers and conductor layers in addition to insulating layers and conductor layers included in the wiring substrate 100, and may not include all of the insulating layers and conductor layers included in the wiring substrate 100. In the drawings to be referenced in the following description, certain portions may be depicted in an enlarged manner in order to facilitate understanding of the manufacturing method of the embodiment. Therefore, it may be possible that structural elements are not depicted in precise proportions in terms of size or length relative to each other.

As illustrated in FIG. 1, the wiring substrate 100 includes a core substrate 10, and insulating layers and conductor layers alternately laminated on each of two main surfaces (a surface (10a) and a surface (10b)) of the core substrate 10 that oppose each other in a thickness direction of the core substrate 10. The wiring substrate 100 has a first surface (100a), which is a surface on the surface (10a) side of the core substrate 10, and a second surface (100b), which is a surface on the surface (10b) side of the core substrate 10. The core substrate 10 includes an insulating layer 28, and conductor layers 17 that are respectively formed on both sides of the insulating layer 28. The core substrate 10 further includes cylindrical through-hole conductors 55 that penetrate the insulating layer 28 and connect the conductor layers 17 on both sides of the insulating layer 28 to each other. Hollow portions of the cylindrical through-hole conductors 55 are filled, for example, with a filler (55a) made of epoxy resin or the like.

In the description of the embodiment, in a thickness direction of a wiring substrate to be manufactured, a side farther from the insulating layer of the core substrate is referred to as an “upper side” or “outer side,” “upward,” or simply “upper.” Further, a side closer to the insulating layer of the core substrate is referred to as a “lower side” or “inner side,” “downward,” or simply “lower.” Further, for each of the structural elements of the wiring substrate to be manufactured, a surface facing away from the insulating layer of the core substrate is also referred to as an “upper surface,” and a surface facing opposite to the upper surface is also referred to as a “lower surface.”

On the surface (10a) of the core substrate 10, an insulating layer 21, a conductor layer 11, an insulating layer 22, a conductor layer 12, an insulating layer 23, a conductor layer 13, an insulating layer 24, a conductor layer 14, an insulating layer 25, an insulating layer 26, and a conductor layer 15 are sequentially laminated. Further, a solder resist 61 constituting the first surface (100a) of the wiring substrate 100 is formed on the insulating layer 26 and the conductor layer 15. The insulating layer 25 can serve as a protective layer for protecting the conductor layer 14 during a manufacturing process of the wiring substrate 100. On the other hand, on the surface (10b) of the core substrate 10, five insulating layers 27 and four conductor layers 16 are alternately laminated, and furthermore, an insulating layer 27 and a conductor layer 16 are sequentially laminated thereon. Then, a solder resist 62 constituting the second surface (100b) of the wiring substrate 100 is formed on the outermost insulating layer 27 and conductor layer 16.

The conductor layers (11 to 17) each include any conductor patterns. As an example, the conductor layer 15 illustrated in FIG. 1 includes connection pads (151, 152) used, for example, for connection to an external component such as a semiconductor integrated circuit device. The connection pads (151, 152) are partially exposed from openings provided in the solder resist 61. Further, the outermost conductor layer 16 among the five conductor layers 16 includes connection pads 161 used, for example, for connection to an external circuit such as a motherboard of an electronic device. The connection pads 161 are partially exposed from openings provided in the solder resist 62. On the other hand, the conductor layer 13, which is an inner-layer conductor layer, includes, as illustrated in FIGS. 1 and 2, a frame-shaped conductor pattern (1b) having a shape that surrounds a specific region.

In each insulating layer among the insulating layers (21 to 27), via conductors 51, via conductors 52, or via conductors 53 are formed that penetrate the insulating layer and connect conductor layers adjacent to each other with the insulating layer interposed therebetween. The via conductors 52 penetrate two insulating layers collectively and connect the conductor layers sandwiching those two insulating layers. For example, the via conductors 52 penetrate the insulating layer 25 and the insulating layer 26 collectively and connect the conductor layer 14 and the conductor layer 15 that sandwich them. The via conductors 52 may connect the connection pads 151 included in the conductor layer 15 and any conductor patterns of the conductor layer 14.

The wiring substrate 100 further includes a component 4 positioned on a surface (23a) of the insulating layer 23. That is, the wiring substrate 100 is a component-embedded substrate. A component-embedded substrate can be manufactured using the method for manufacturing a wiring substrate according to the embodiment. The component 4 in the example of FIGS. 1 to 3 has multiple electrodes 41 on its upper surface and is fixed to the surface (23a) of the insulating layer 23 by an adhesive (4a). The component 4 is accommodated inside a cavity 30. The cavity 30 is formed by an opening 3 penetrating the insulating layer 24 and a portion of the surface (23a) of the insulating layer 23 that is exposed in the opening 3.

In the example of FIGS. 1 to 3, the opening 3 penetrates collectively the insulating layer 24 and the insulating layer 25 that is directly formed on the insulating layer 24. The cavity 30 is filled with a filling resin (26a) integral with the insulating layer 26, that is, with a part of a resin material constituting the insulating layer 26. In the example of FIGS. 1 to 3, the component 4 is entirely accommodated inside the cavity 30, and the component 4 is covered and sealed by the filling resin (26a) that fills the cavity 30. Therefore, the insulating layer 26 functions as a sealing layer for the component 4.

Examples of the component 4 include electronic components such as active components (such as semiconductor integrated circuit devices and transistors) and passive components (such as electrical resistors). Further, the component 4 may be a wiring member (for example, an interposer) including fine wirings formed on a semiconductor substrate. When the component 4 is a semiconductor component, the component 4 may be sealed (packaged) with resin or metal, or may be in a state of a bare chip that is not sealed. Further, a component 4 mounted in a bare chip state may be mounted in a face-up manner as in the example of FIGS. 1 to 3, or may be mounted in a face-down manner. In the example of FIGS. 1 to 3, a bottom surface of the component 4, which is a surface on an opposite side with respect to an electrode surface on which the electrodes 41 are provided, is fixed to the surface (23a) of the insulating layer 23.

In the insulating layer 26 that covers the component 4, multiple through conductors 54 are formed that penetrate the insulating layer 26, or the insulating layer 26 and the filling resin (26a). The electrodes 41 of the component 4 and the connection pads 152 of the conductor layer 15 are connected by the through conductors 54. Preferably, a minimum width of the through conductors 54 is smaller than a minimum width of the via conductors 52, and a minimum spacing between the through conductors 54 is smaller than a minimum spacing between the via conductors 52. Similarly, preferably, a minimum width of the connection pads 152 is smaller than a minimum width of the connection pads 151, and a minimum spacing between the connection pads 152 is smaller than a minimum spacing between the connection pads 151. The “width” of each conductor pad such as the connection pads (151, 152) is a longest distance between any two points on an outer periphery on an upper surface of each conductor pad. The “width” of the through conductors 54 and each via conductor is also defined in the same manner as the “width” of each conductor pad.

As illustrated in FIGS. 1 to 3, in the wiring substrate 100, the component 4 positioned in the cavity 30 is surrounded, in plan view, by the frame-shaped conductor pattern (1b) of the conductor layer 13. That is, the frame-shaped conductor pattern (1b) is formed so as to surround a component mounting region provided for the component 4. The term “plan view” means viewing an object along a thickness direction of the wiring substrate 100.

The frame-shaped conductor pattern (1b) illustrated in FIGS. 1 to 3 has an inner peripheral portion exposed inside the cavity 30 and an outer peripheral portion that is covered by the insulating layer 24 on an outer side of the inner peripheral portion. Therefore, a lower end of a wall surface (3a) of the opening 3 is in contact with an upper surface of the frame-shaped conductor pattern (1b). That is, a portion (the inner peripheral portion) of the frame-shaped conductor pattern (1b) protrudes from the wall surface (3a) of the opening 3 into the interior of the opening 3. On the other hand, in the wiring substrate 100, a recess recessed so as to accommodate the entire frame-shaped conductor pattern is not formed in the wall surface (3a) of the opening 3. Therefore, in the wiring substrate 100, unfilled portions during filling of the opening 3 with the filling resin (26a), that is, voids, are unlikely to occur. It is thought that, in use of the wiring substrate 100, cracks or interlayer delamination due to thermal expansion or thermal contraction of voids are unlikely to occur.

The insulating layers (21 to 28) are mainly formed of any insulating resin. Examples of the insulating resin used for forming the insulating layers include thermosetting resins such as epoxy resin, bismaleimide triazine resin (BT resin), or phenol resin, as well as thermoplastic resins such as fluororesin, liquid crystal polymer (LCP), fluorinated ethylene (PTFE) resin, polyester (PE) resin, and modified polyimide (MPI) resin. The resins listed as materials for the insulating layers are merely examples of materials capable of forming the insulating layers. The insulating layers can be formed of any material that can support the conductor layers in the wiring substrate 100 and can provide insulation between the conductor layers.

In the wiring substrate 100 of FIG. 1, the insulating layer 28 contains a core material (reinforcing material) (28a) made of, for example, glass fiber, aramid fiber, or the like. Although not illustrated in FIG. 1, the insulating layers other than the insulating layer 28 may also each contain a core material made of glass fiber or the like. The insulating layers (21 to 28) may each further contain a filler made of, for example, silicon oxide, alumina, mullite, or the like.

The conductor layers (11 to 17), as well as the via conductors (51 to 53), the through conductors 54, and the through-hole conductors 55, are formed using any metal such as copper or nickel. In FIG. 1, each conductor layer is depicted as being composed of a single layer, but each conductor layer may have a multilayer structure. The conductor layers 17 may each have, for example, a three-layer structure or a five-layer structure including a metal foil, an electroless plating film or a sputtering film, and an electrolytic plating film. On the other hand, the conductor layers (11 to 16), the via conductors (51 to 53), the through conductors 54, and the through-hole conductors 55 may each have a two-layer structure including an electroless plating film or a sputtering film, and an electrolytic plating film.

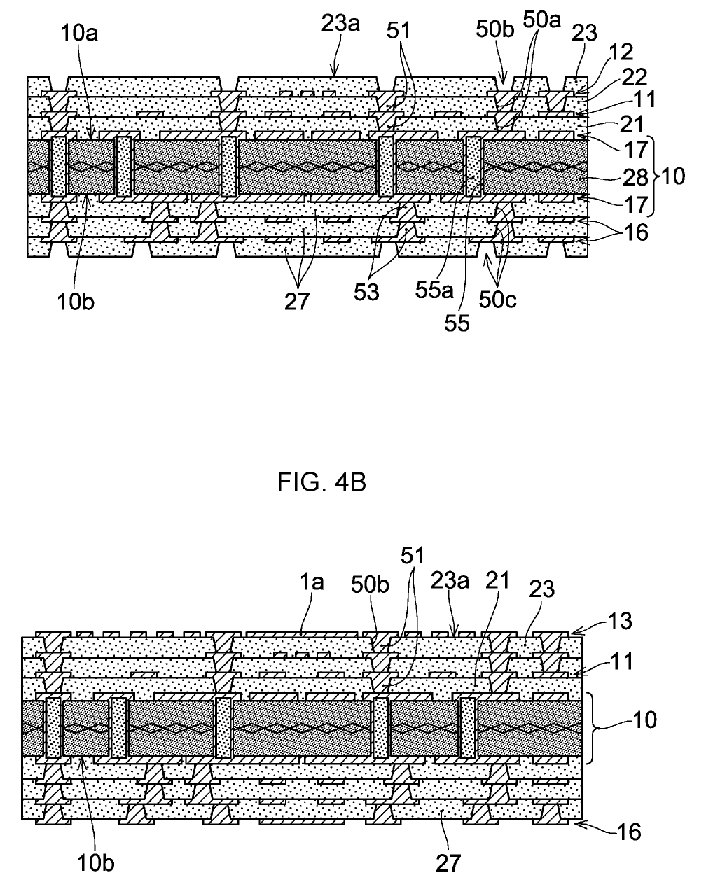

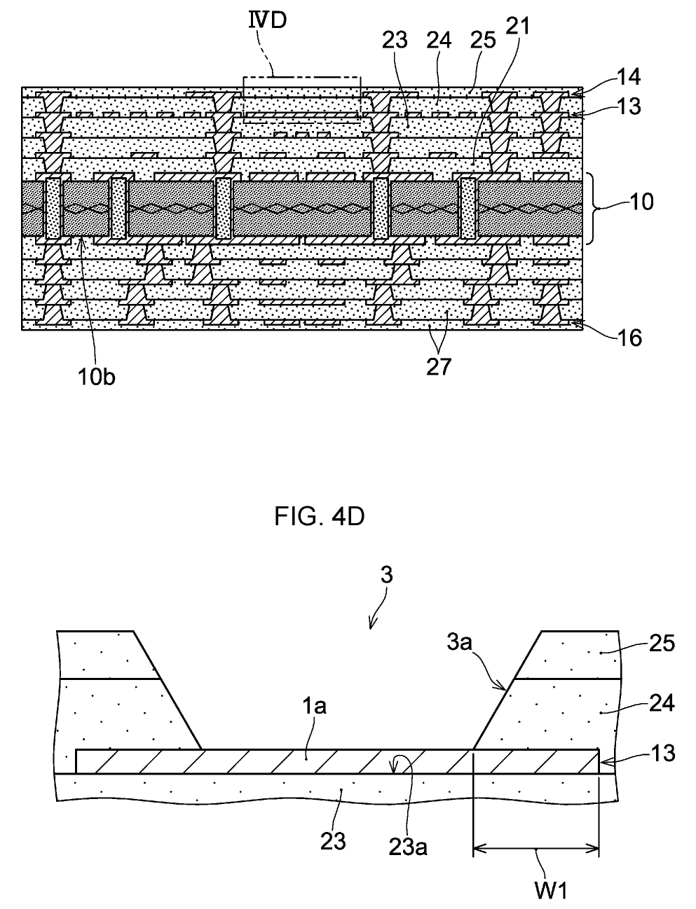

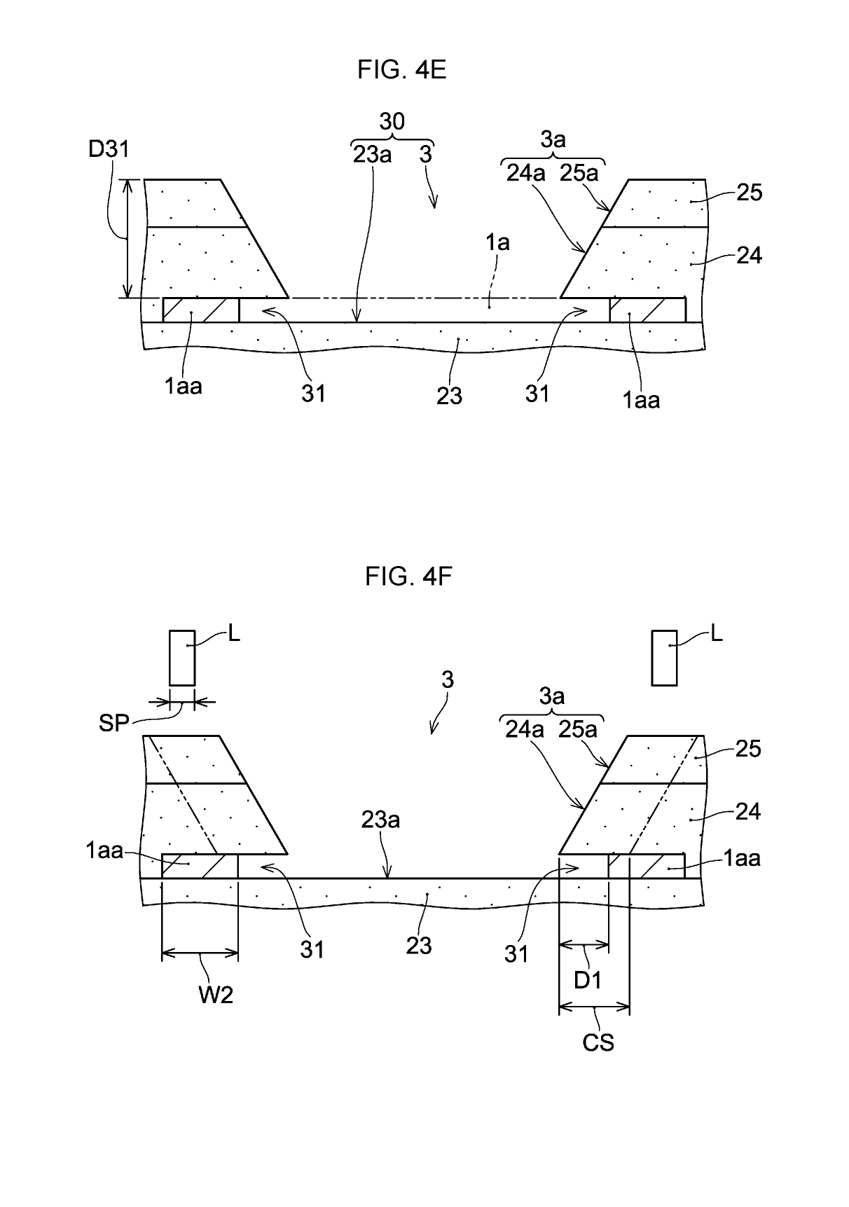

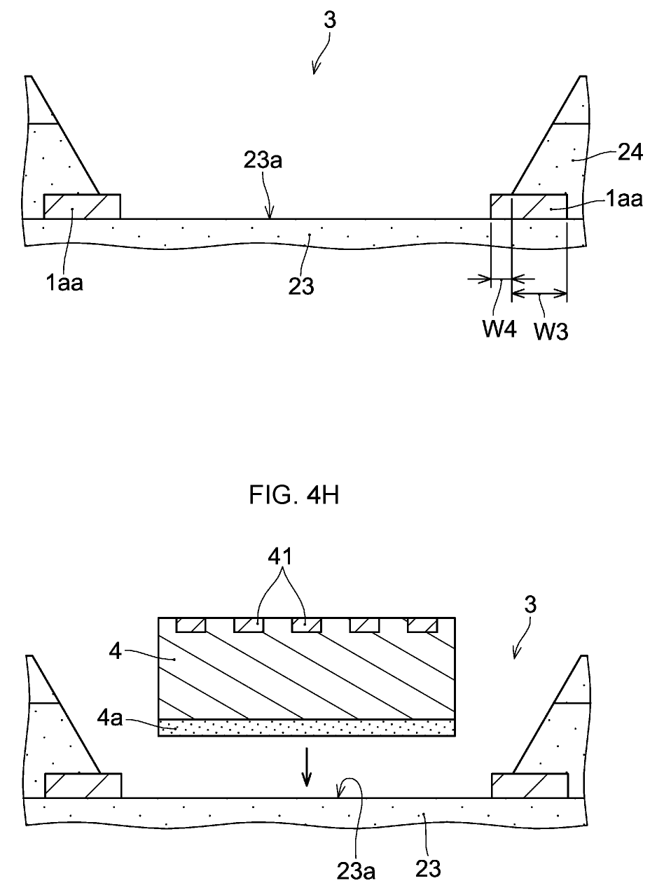

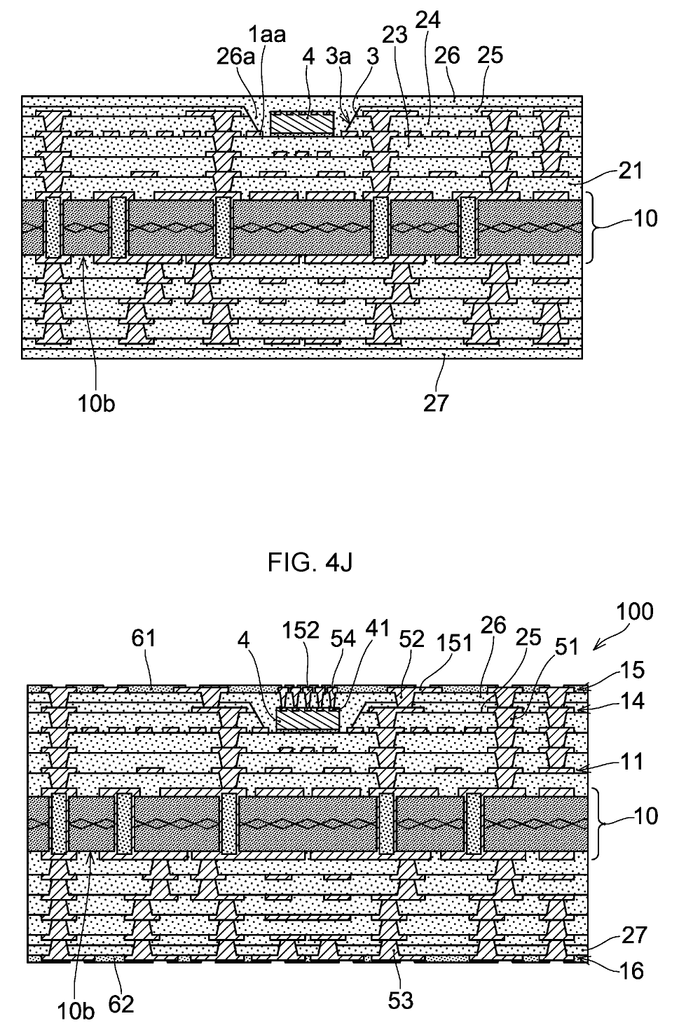

Next, a method for manufacturing the wiring substrate of the embodiment is described with reference to FIGS. 4A – 4J using the wiring substrate 100 of FIG. 1 as an example. Structural elements formed in the method for manufacturing the wiring substrate to be described below may be formed using the materials exemplified as the materials of the corresponding structural elements in the description of the wiring substrate 100 of FIG. 1, unless otherwise specified.

As illustrated in FIG. 4A, in manufacturing the wiring substrate 100 of FIG. 1, first, the core substrate 10 is formed, and predetermined insulating layers and conductor layers are formed on both sides of the core substrate 10. For example, a starting substrate (for example, a double-sided copper-clad laminated plate) is prepared that includes an insulating layer, which is to become the insulating layer 28 of the core substrate 10, and metal foils that are respectively laminated on both sides of the insulating layer. The through-hole conductors 55 are formed by forming through holes and panel plating. The hollow portions of the cylindrical through-hole conductors 55 are filled with, for example, the filler (55a) containing epoxy resin or the like. Furthermore, panel plating is performed by, for example, electroless plating and electrolytic plating. Then, by patterning using a subtractive method, the conductor layers 17 having desired conductor patterns are formed. The core substrate 10 including the insulating layer 28 and the conductor layers 17 on both surfaces thereof is obtained.

On the surface (10a) of the core substrate 10, the insulating layer 21 is formed, and the conductor layer 11 is formed on the insulating layer 21. Furthermore, the insulating layer 22 is formed on the insulating layer 21 and the conductor layer 11, and the conductor layer 12 is formed on the insulating layer 22. Then, on the insulating layer 22 and the conductor layer 12, the insulating layer 23 having the surface (23a) as a surface (upper surface) on an opposite side with respect to the insulating layer 22 side is formed. On the surface (10b) of the core substrate 10, two sets of insulating layers 27 and conductor layers 16 are formed, and an insulating layer 27 is further formed. A portion of the surface (23a) of the insulating layer 23 is exposed in the opening 3 (see FIG. 4D) by formation of the opening 3 that is formed in a later process. In the method for manufacturing a wiring substrate according to the embodiment, an insulating layer having a surface that is partially exposed by formation of an opening in which a component is to be positioned is also referred to as a first insulating layer. In manufacturing the wiring substrate 100 of FIG. 1, the insulating layer 23 can be the first insulating layer.

In forming each of the insulating layers (21 to 23) and the insulating layers 27, for example, a film-like epoxy resin is laminated and thermocompression bonded on the core substrate 10 or on an insulating layer and a conductor layer formed earlier. As a result, the insulating layers (21 to 23) and the insulating layers 27 are formed. In the insulating layers (21, 22), through holes (50a) for forming the via conductors 51 are formed, and in the insulating layer 23 as well, through holes (50b) for forming the via conductors 51 (see FIG. 4B) are formed. On the other hand, in the insulating layers 27, through holes (50c) for forming the via conductors 53 are formed. The through holes (50a) and the through holes (50c) are formed by, for example, irradiation with CO₂ laser light or the like. After the formation of the through holes (50a to 50c), when necessary, smear inside the through holes is removed, for example, by exposing inner walls of the through holes (50a to 50c) to a treatment solution such as an alkaline permanganate solution.

The conductor layers (11, 12), and the conductor layers 16, may be formed, for example, using a semi-additive method. That is, a metal film is formed by electroless plating or sputtering on an entire surface of an insulating layer serving as a base for a conductor layer, and in the through holes formed in the insulating layer. A plating film is formed by pattern plating including electrolytic plating using the metal film as a power feeding layer. The via conductors 51 are formed in the through holes (50a) formed in the insulating layer 21 or the insulating layer 22, and the via conductors 53 are formed in the through holes (50c) formed in the two insulating layers 27 on the core substrate 10 side. After that, unwanted portions of the metal film are removed, for example, by etching. As a result, the conductor layer 11, the conductor layer 12, and the conductor layers 16, including predetermined conductor patterns, are formed.

After the formation of the insulating layer 23, as illustrated in FIG. 4B, the conductor layer 13 is formed on the surface (23a) of the insulating layer 23. The via conductor 51 are formed in the through holes (50b) formed in the insulating layer 23. The conductor layer 13 is formed so as to include a conductor pad (1a). That is, the manufacturing method of the embodiment includes forming a conductor layer including a conductor pad on a surface of the first insulating layer. The conductor layer 13 and the via conductors 51 in the insulating layer 23 are formed, for example, using a method similar to that for the conductor layer 11 and the via conductors 51 in the insulating layer 21. As an example, the conductor layer 13 is formed using a semi-additive method. By using a plating mask having appropriate opening patterns for pattern plating performed in a semi-additive method, the conductor layer 13 including the conductor pad (1a) can be formed. However, the method of forming the conductor layer 13 is not limited to a semi-additive method, and any method can be used for forming the conductor layer 13. On the surface (10b) side of the core substrate 10, a conductor layer 16 is further formed on the outermost insulating layer 27 using any method.

As illustrated in FIG. 4C, the insulating layer 24 covering the insulating layer 23 and the conductor layer 13 is formed. In this way, the manufacturing method of the embodiment includes forming an insulating layer that covers the first insulating layer and the conductor layer. In the method for manufacturing a wiring substrate according to the embodiment, an insulating layer that is directly formed on the first insulating layer (the insulating layer 23 in the example of FIG. 4C) is also referred to as a second insulating layer. In manufacturing the wiring substrate 100, the insulating layer 24 is an insulating layer that is also referred to as the second insulating layer. On the surface (10b) side of the core substrate 10, an insulating layer 27 is further formed. The insulating layer 24 and the further formed insulating layer 27 are formed, as an example, using a method similar to that for the insulating layer 21 and the like; however, the method of forming these insulating layers is not particularly limited.

After the formation of the insulating layer 24, the conductor layer 14 is formed on an upper surface of the insulating layer 24, and the insulating layer 25 is formed on the conductor layer 14 and the insulating layer 24. The conductor layer 14 is formed, as an example, using a semi-additive method, similar to the conductor layer 11 and the like. The insulating layer 25 is formed, as an example, using a method similar to that for the insulating layer 21 and the like. On the surface (10b) side of the core substrate 10, a conductor layer 16 is further formed on the outermost insulating layer 27 using any method, and an insulating layer 27 is further formed thereon using any method.

As illustrated in FIG. 4D, after formation of the insulating layer 25, the opening 3 is formed that penetrates the insulating layer 25 and the insulating layer 24 and exposes the conductor pad (1a) of the conductor layer 13. FIG. 4D illustrates a state after formation of the opening 3 at a location corresponding to a portion (IVD) illustrated in FIG. 4C (FIGS. 4E to 4H, which are referred to later, also illustrate the same portion as that illustrated in FIG. 4D). The opening 3 is formed by irradiation with laser light (not illustrated). The opening 3 is formed in a predetermined region including a region where the component 4 (see FIG. 1) is to be mounted.

The laser light for forming the opening 3 is irradiated, in plan view, in a range where the conductor pad (1a) is formed. Further, the opening 3 is formed such that a vicinity portion of an outer edge of the conductor pad (1a) remains covered by the insulating layer 24 without being exposed in the opening 3 after formation of the opening 3. Therefore, after formation of the opening 3, a central portion of the conductor pad (1a) is exposed in the opening 3; however, a vicinity portion of the outer edge of the conductor pad (1a) remains covered by the insulating layer 24 and is not exposed. In this way, the manufacturing method of the embodiment includes forming, by irradiation with laser light, the opening 3 that penetrates the second insulating layer (the insulating layer 24 in the example of FIG. 4D) and partially exposes the conductor pad (1a).

After formation of the opening 3, a width (W1) of a portion of the conductor pad (1a) that is covered by the insulating layer 24 (a non-exposed portion of the conductor pad (1a) after formation of the opening 3) may be, for example, about 30 μm. That is, the laser light for forming the opening 3 may be irradiated such that, from the outer edge of the conductor pad (1a) toward the central portion side of the conductor pad (1a), a non-exposed portion with a width (W1) of about 30 μm is formed in the conductor pad (1a). By providing the non-exposed portion with such a width (W1) in the conductor pad (1a), adjustment of an irradiation position of the laser light may be facilitated in a process of reducing a depth of a recess 31 (see FIG. 4F) to be described later. Further, it may be possible to suppress unintended irradiation of the laser light to outside of the conductor pad (1a). The width (W1) of the non-exposed portion of the conductor pad (1a) is, in plan view, a distance between an outer edge of the formed opening 3 in contact with the conductor pad (1a) and the outer edge of the conductor pad (1a) outside the outer edge of the opening 3 in a direction orthogonal to the outer edge of the opening 3 (hereinafter, this direction is also referred to as the “first direction”).

In the example of FIG. 4D, the opening 3 is formed so as to have a wall surface (3a) that is inclined with respect to a direction perpendicular to the surface (23a) of the insulating layer 23 such that an opening area of the opening 3 becomes smaller on the insulating layer 23 side. By adjusting irradiation conditions of the laser light for forming the opening 3, the opening 3 having a shape as illustrated in FIG. 4D can be formed. It is also possible that the opening 3 is formed so as to have a substantially constant opening area over the entire opening 3 in its depth direction.

Examples of the laser light used for forming the opening 3 include laser light generated by a CO₂ laser or a YAG laser. However, any other laser light can be used for forming the opening 3. The laser light used for forming the opening 3, such as, for example, CO₂ laser light, is irradiated while moving an irradiation position over an entire region where the opening 3 is to be formed. Preferably, the conductor pad (1a) is used as a laser stopper that prevents the laser light from reaching the insulating layer 23. The conductor pad (1a) protects the insulating layer 23 from stress associated with formation of the opening 3. After formation of the opening 3, when necessary, smear generated by formation of the opening 3 is removed using, for example, a treatment solution such as an alkaline permanganate solution.

As illustrated in FIG. 4E, the exposed portion of the conductor pad (1a) and the non-exposed portion around the exposed portion of the conductor pad (1a) are etched. In the example of FIG. 4E, by etching, the exposed portion of the conductor pad (1a) is removed, and only a part of the surrounding non-exposed portion is removed, leaving a non-removed portion of the conductor pad (1a) (a remaining portion (1aa)). The remaining portion (1aa) remains covered by the insulating layer 24 at a position recessed from an inner wall surface (24a) of the insulating layer 24 exposed in the opening 3. Further, by etching the non-exposed portion of the conductor pad (1a), a recess 31 that exposes the remaining portion (1aa) is formed in the inner wall surface (24a) of the insulating layer 24. That is, the recess 31 is formed such that the remaining portion (1aa) faces the recess 31, and therefore a surface thereof is exposed in the recess 31. In the example of FIG. 4E, a surface of the remaining portion (1aa) on the opening 3 side is exposed in the recess 31.

In this way, the manufacturing method of the embodiment includes etching the exposed portion of the conductor pad (1a) and the surrounding non-exposed portion such that the remaining portion (1aa) of the conductor pad (1a) remains at a position recessed from the inner wall surface (24a) of the insulating layer 24 exposed in the opening 3. The manufacturing method of the embodiment further includes forming the recess 31 in the inner wall surface (24a) of the insulating layer 24 by etching the non-exposed portion of the conductor pad (1a), the recess 31 exposing a surface of the remaining portion (1aa) of the conductor pad (1a). The recess 31 has a depth in a direction outward from the opening 3 in plan view. The recess 31 may be formed in the inner wall surface (24a) of the insulating layer 24 over an entire circumference of the opening 3 in plan view, and may be formed in a groove shape along the circumferential direction of the opening 3 in plan view.

The etching of the exposed portion of the conductor pad (1a) and the surrounding non-exposed portion is performed, for example, by wet etching using any appropriate etching solution capable of dissolving the conductor pad (1a). The non-exposed portion of the conductor pad (1a) is etched because, for example, following the removal of the exposed portion of the conductor pad (1a), the portion of the conductor pad (1a) that is covered by the insulating layer 24 is also exposed to the etching solution sequentially from the opening 3 side. The remaining portion (1aa) that remains after etching of the non-exposed portion of the conductor pad (1a) mainly has a frame-shaped form along an outer periphery of the opening 3, and constitutes the frame-shaped conductor pattern (1b) in the wiring substrate 100 of FIG. 1.

By formation of the opening 3 and removal of the exposed portion of the conductor pad (1a), the cavity 30 constituted by the opening 3 penetrating the insulating layer 25 and the insulating layer 24, and the surface (23a) of the insulating layer 23, is provided. A bottom surface of the cavity 30 is constituted by a portion of the surface (23a) of the insulating layer 23 that is exposed in the opening 3. As an example, a cavity 30 having a depth (D31) of about 100 μm to 150 μm may be provided. Preferably, a cavity 30 having a depth (D31) greater than a thickness of the component 4 to be positioned in the opening 3 in a later process is provided.

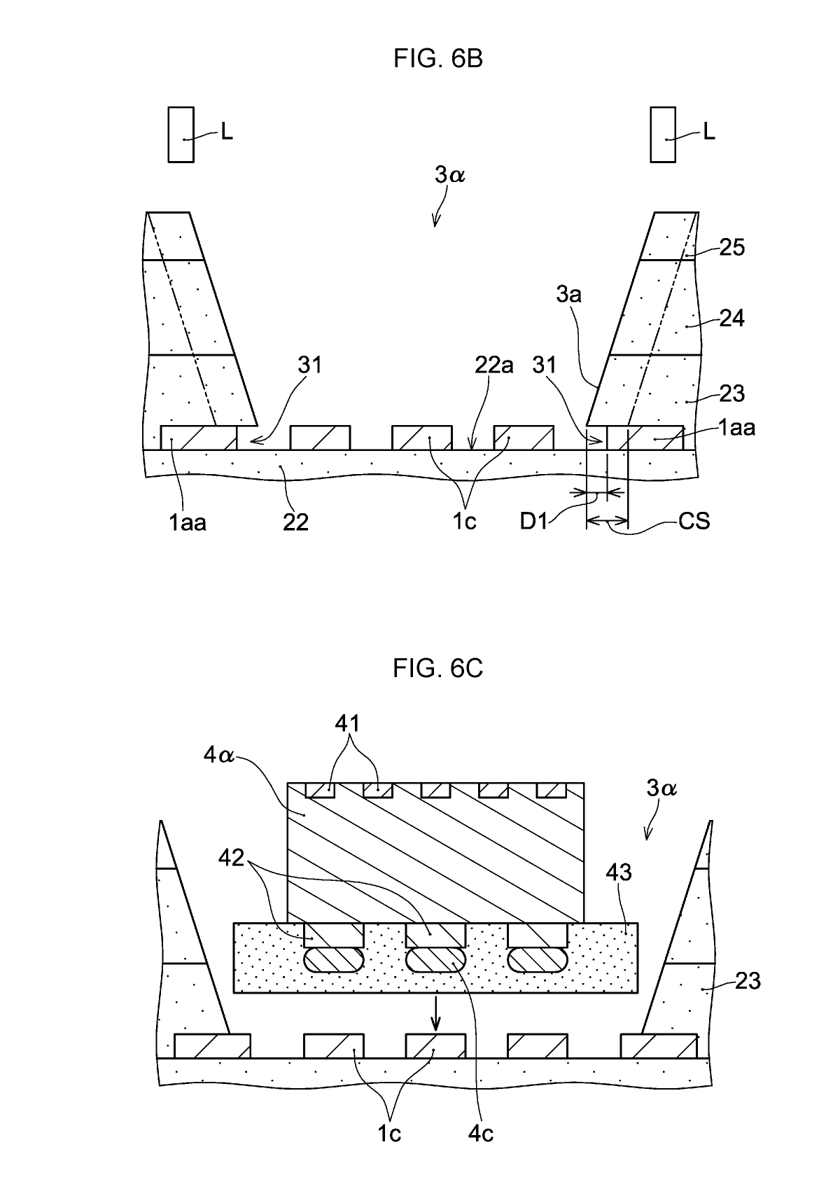

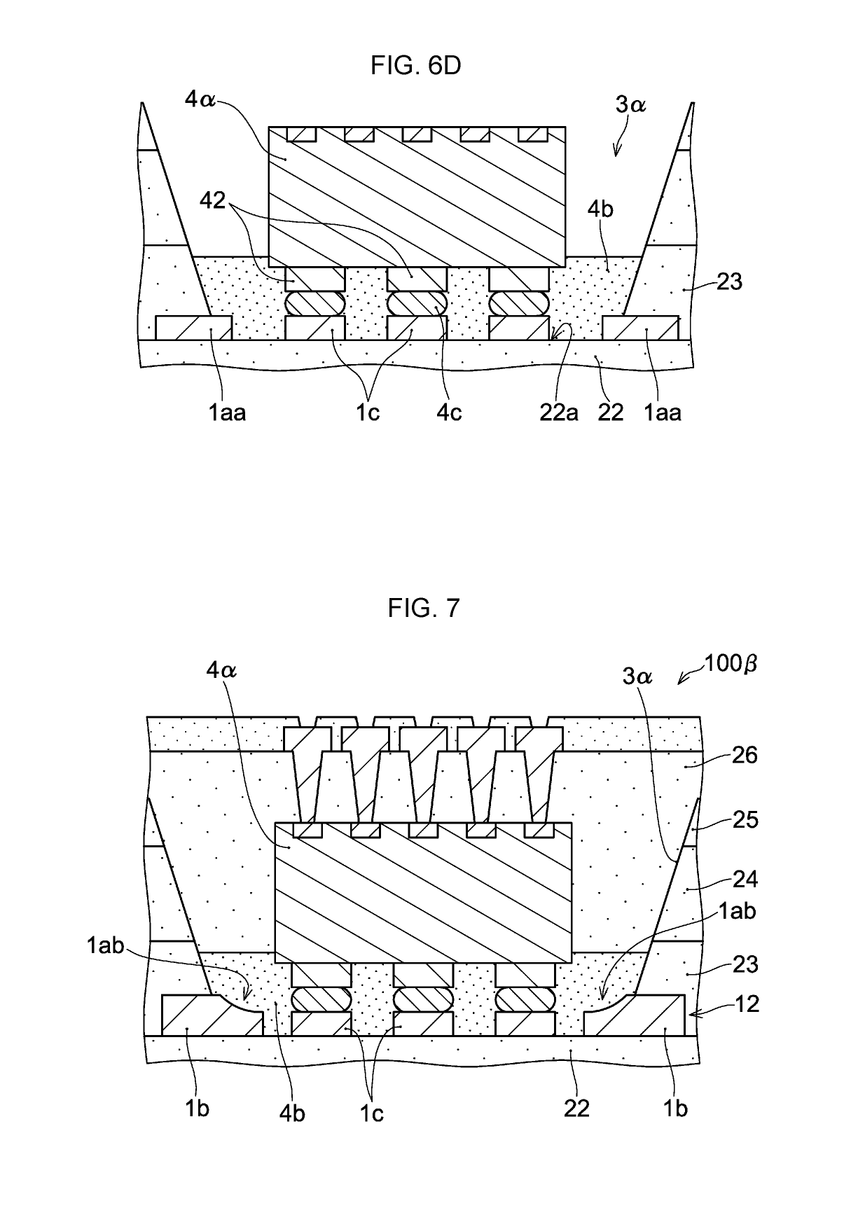

In the manufacturing method of the embodiment, as will be described later with reference to FIG. 6B, the exposed portion may be partially removed so that a part of the exposed portion of the conductor pad (1a) remains after etching. That is, in the manufacturing method of the embodiment, the exposed portion of the conductor pad (1a) in the opening 3 is at least partially removed by etching.

The method for manufacturing a wiring substrate according to the embodiment further includes cutting an inner wall surface of the second insulating layer (the inner wall surface (24a) of the insulating layer 24 in FIG. 4E) so as to reduce the depth of the recess 31. “Reducing the depth of the recess 31” means making the depth of the recess 31 in the direction outward from the opening 3 smaller than the depth immediately after formation of the recess 31. Therefore, “reducing the depth of the recess 31” also includes making the depth of the recess 31 zero, that is, eliminating the recess 31. With reference to FIGS. 4F and 4G, cutting the inner wall surface (24a) so as to reduce the depth of the recess 31 in the manufacturing method of the embodiment is further described. FIGS. 4F and 4G illustrate an example in which the recess 31 is eliminated as a result of reducing the depth of the recess 31.

As illustrated in FIG. 4F, the recess 31 formed with removal of the exposed portion of the conductor pad (1a) (see FIG. 4D) has a depth (D1) immediately after formation of the recess 31. In the method for manufacturing a wiring substrate according to the embodiment, after formation of the recess 31, the inner wall surface (24a) of the insulating layer 24 is cut such that the depth of the recess 31 becomes smaller than the depth (D1). FIG. 4F illustrates an example in which the inner wall surface (24a) is cut by irradiation with laser light (L). The laser light (L) is irradiated around the already formed opening 3 along the outer edge of the opening 3. By ablation caused by the irradiation with the laser light (L), a portion of the insulating layer 25 in the vicinity of the opening 3 is removed, and subsequently, a portion of the insulating layer 24 in the vicinity of the opening 3 is removed. In this way, in the manufacturing method of the embodiment, cutting the inner wall surface of the second insulating layer (the insulating layer 24 in FIG. 4F) may include irradiating laser light around the opening 3. The depth of the recess 31 can be reduced using any method, such as, for example, drilling, not limited to irradiation with laser light.

The laser light (L) may be irradiated onto the wall surface (3a) of the opening 3, that is, onto the inner wall surface (24a) of the insulating layer 24 and an inner wall surface (25a) of the insulating layer 25 that are exposed in the opening 3. By irradiation with the laser light (L), the inner wall surface (24a) of the insulating layer 24 and the inner wall surface (25a) of the insulating layer 25 may be cut by a predetermined cutting allowance (CS). By cutting the inner wall surface (24a) of the insulating layer 24 and the inner wall surface (25a) of the insulating layer 25, the already formed opening 3 may be enlarged in plan view. That is, in the manufacturing method of the embodiment, reducing the depth of the recess may include making an opening area of the opening larger immediately after formation of the opening.

Further, the laser light (L) may be irradiated onto a portion around the opening 3 on the upper surface of the insulating layer 25, and after an irradiated portion of the insulating layer 25 is removed by the irradiation, the laser light (L) may be irradiated onto a portion around the opening 3 on the upper surface of the insulating layer 24. When the opening 3 is formed by irradiation with laser light in the process described with reference to FIG. 4D so as to have the wall surface (3a) inclined with respect to a direction perpendicular to the surface (23a) of the insulating layer 23, the laser light (L) may be irradiated under conditions similar to those of the laser light used for forming the opening 3. In this case, an inclination substantially the same as the inclination of the wall surface (3a) immediately after formation of the opening 3 may be maintained in the wall surface (3a) even after irradiation with the laser light (L).

That is, the inner wall surface (25a) may be cut by a substantially constant amount over the entire insulating layer 25 in a thickness direction thereof, and further, the inner wall surface (24a) may be cut by a substantially constant amount over the entire insulating layer 24 in a thickness direction thereof. In this way, a cutting width of the inner wall surface of the insulating layer 25 and/or the insulating layer 24 may be constant in the thickness direction of the insulating layer 25 and the insulating layer 24. However, the cutting width of the inner wall surface of the insulating layer 25 and/or the insulating layer 24 may vary in the thickness direction of the insulating layer 25 and the insulating layer 24. The “cutting width” of the inner wall surface of each of the insulating layer 25 and the insulating layer 24 is a length of the cutting allowance (CS) in the first direction.

The laser light (L) is preferably irradiated so as not to be directly irradiated onto the surface (23a) of the insulating layer 23. The remaining portion (1aa) of the conductor pad (1a) can be used as a stopper for the laser light (L). Preferably, the laser light (L) is irradiated with a spot diameter (SP) smaller than a width (W2) of the remaining portion (1aa).

In the example of FIG. 4F, the cutting width (the length of the cutting allowance (CS)) of the inner wall surface of each of the insulating layer 25 and the insulating layer 24 is larger than the depth (D1) of the recess 31 immediately after formation of the recess 31. Therefore, after irradiation with the laser light (L), the recess 31 is eliminated as illustrated in FIG. 4G. Further, the remaining portion (1aa) of the conductor pad (1a) (see FIG. 4D) partially protrudes from the insulating layer 24, and therefore a part of the remaining portion (1aa) is exposed in the opening 3. FIG. 4G illustrates an example of a state after irradiation with the laser light (L) of FIG. 4F.

As illustrated in the example of FIG. 4G, a portion of the remaining portion (1aa) that is not exposed in the opening 3 remains covered by the insulating layer 24. Unlike the example illustrated in FIG. 4G, an entire upper surface of the remaining portion (1aa) may be exposed from the insulating layer 24. In this way, in the manufacturing method of the embodiment, cutting of the inner wall surface of the second insulating layer (the insulating layer 24 in FIG. 4G) may include exposing the remaining portion of the conductor pad from the second insulating layer after removing the exposed portion of the conductor pad.

After the process of reducing the depth of the recess 31 (see FIG. 4F), a width (W3) of the portion of the remaining portion (1aa) that is covered by the insulating layer 24 without being exposed in the opening 3 (the non-exposed portion) may be, for example, substantially 10 μm. Further, a width (W4) of the exposed portion of the remaining portion (1aa) that is exposed in the opening 3 may be, for example, substantially 10 μm. That is, the laser light for reducing the depth of the recess 31 may be irradiated such that a non-exposed portion is formed with a width (W3) of substantially 10 μm from an outer edge toward an inner edge of the frame-shaped remaining portion (1aa), and an exposed portion is formed with a width (W4) of substantially 10 μm from the inner edge toward the outer edge of the remaining portion (1aa). By irradiating the laser light in this manner, it may be possible to suppress unintended irradiation of laser light onto the surface (23a) of the insulating layer 23 on an outer side and inner side of the remaining portion (1aa). The width (W3) of the non-exposed portion of the remaining portion (1aa) is a distance in the first direction between an outer edge of the opening 3 in contact with the remaining portion (1aa) and an outer edge of the remaining portion (1aa), after the process of reducing the depth of the recess 31. The width (W4) of the exposed portion is a distance in the first direction between the outer edge of the opening 3 in contact with the remaining portion (1aa) and an inner edge of the remaining portion (1aa), after the process of reducing the depth of the recess 31.

As described with reference to FIGS. 4F to 4G, the method for manufacturing a wiring substrate according to the embodiment includes reducing the depth of the recess 31 formed in the wall surface (3a) of the opening 3 with removal of the exposed portion of the conductor pad (1a) exposed by formation of the opening 3. Therefore, it is thought that, in filling the opening 3 with resin, which will be described later, occurrence of voids due to the resin being unable to enter the recess 31 can be suppressed. Therefore, it is thought that voids are unlikely to occur in the opening 3, and thus, cracks and delamination between structural elements due to expansion/contraction of voids are unlikely to occur in the opening 3 or in a surrounding portion thereof. The depth of the recess 31 may be reduced such that the recess 31 remains with a depth smaller than the depth immediately after formation of the recess 31. Even in such a case, occurrence of voids in the opening 3 may be suppressed.

As illustrated in FIG. 4H, the manufacturing method of the embodiment includes positioning the component 4 in the opening 3. As described above, the component 4 may be an active component such as a semiconductor integrated circuit device, a passive component such as an electrical resistor, or a wiring member including fine wirings. As described above, the component 4 may be in a packaged state or in a bare chip state, and may be mounted in a face-up manner or in a face-down manner. In the example of FIG. 4H, with the electrodes 41 facing upward, the component 4 is placed on the surface (23a) of the insulating layer 23 exposed at a bottom surface of the opening 3. The component 4 includes, on a surface on an opposite side with respect to the surface on which the electrodes 41 are formed, a die attach film (4a) that functions as a bonding material to the surface (23a). The die attach film (4a) is not particularly limited, but is formed of, for example, an epoxy-based resin or the like.

After placing the component 4 on the surface (23a) of the insulating layer 23, preferably, the component 4 is pressed toward the surface (23a) under vacuum to remove any voids that may have been trapped under the component 4 during placement of the component 4. When necessary, the component 4 is bonded to the surface (23a) by a treatment such as heating that melts the die attach film (4a). The component 4 does not necessarily need to include the die attach film (4a), and may be bonded to the surface (23a) by a die bond material (not illustrated) separately supplied onto the surface (23a).

After positioning the component 4, preferably, the upper surface of the component 4 is roughened by, for example, a surface oxidation treatment called blackening treatment or browning treatment, or a micro-etching treatment using an acidic solvent. By the roughening treatment of the upper surface of the component 4, adhesion strength between the insulating layer 26 (see FIG. 4I) formed in a later process and the upper surface of the component 4 is improved.

As illustrated in FIG. 4I, the insulating layer 26 is formed on the insulating layer 25. On the surface (10b) side of the core substrate 10, an insulating layer 27 is further formed. The insulating layer 26 and the further formed insulating layer 27 are formed, as an example, using a method similar to that for the insulating layer 21 and the like; however, the method of forming these insulating layers is not particularly limited. The insulating layer 26 may be formed by thermocompression bonding of a film-like resin as described above with regard to formation of the insulating layer 21 and the like, or by application of a liquid resin. During the formation, a constituent material such as epoxy resin constituting the insulating layer 26 becomes fluid and flows into the opening 3. Then, the opening 3 is filled with the filling resin (26a) made of the constituent material of the insulating layer 26. As a result, the component 4 is covered by the filling resin (26a) made of, for example, epoxy resin or the like, and is sealed inside the opening 3. That is, the insulating layer 26 is formed integrally with the filling resin (26a) and seals the component 4 inside the opening 3. In the manufacturing method of the embodiment, an insulating layer (sealing layer) that is formed integrally with the resin filling the opening 3 is also referred to as a third insulating layer. In manufacture of the wiring substrate 100 of FIG. 1, the insulating layer 26 is an insulating layer that is also referred to as the third insulating layer.

In this way, the manufacturing method of the embodiment includes filling the opening with a resin such as the filling resin 26. Further, the manufacturing method of the embodiment may include forming the third insulating layer (the insulating layer 26 in the example of FIG. 4I) on the second insulating layer (the insulating layer 24 in the example of FIG. 4I) on an opposite side with respect to the first insulating layer (the insulating layer 23 in the example of FIG. 4I). And, forming the third insulating layer may include filling the opening with a resin such as the filling resin (26a), and covering the component inside the opening.

In the example of FIG. 4I, by filling the opening 3 with the filling resin (26a), the remaining portion (1aa) of the conductor pad (1a) (see FIG. 4D) that is exposed in the opening 3 is covered by the filling resin (26a). Therefore, a short-circuit failure due to unintended contact between the remaining portion (1aa) and any conductor may be prevented. In this way, in the manufacturing method of the embodiment, filling the opening with a resin such as the filling resin (26a) may include covering the remaining portion of the conductor pad with the resin.

In the method for manufacturing a wiring substrate according to the embodiment, as described above, the depth of the recess 31 (see FIG. 4E) formed in the wall surface (3a) of the opening 3 with removal of the exposed portion of the conductor pad exposed by formation of the opening 3 is reduced. Therefore, it is thought that occurrence of voids during filling of the opening 3 with resin can be suppressed. Therefore, cracks or delamination between structural elements due to expansion/contraction of voids are unlikely to occur in the opening 3 or in a surrounding portion thereof. Further, in the examples illustrated in FIG. 4I and the like, the component 4 is positioned in the opening 3 after the exposed portion of the conductor pad in the opening 3 has been removed. Therefore, compared to a case where the component 4 is placed on the conductor pad, it may be possible to manufacture a wiring substrate that includes an opening 3 having a smaller depth and thus has a smaller thickness.

As illustrated in FIG. 4J, the conductor layer 15, the via conductors 52, and the through conductors 54 are formed. The conductor layer 15 is formed on the insulating layer 26, and the conductor layer 15 is provided with the connection pads (151, 152) used for connection to an external circuit. The conductor layer 15 is connected to the conductor layer 14 by the via conductors 52 that penetrate the insulating layer 26 and the insulating layer 25. And, the connection pads 152 are connected to the electrodes 41 of the component 4 by the through conductors 54 that penetrate the insulating layer 26 above the component 4. The connection pads 152 and the through conductors 54 may be formed, for example, at a pitch of about 45 μm to 100 μm. On the other hand, on the surface (10b) side of the core substrate 10, a conductor layer 16 is further formed as the outermost conductor layer on the surface (10b) side, and the via conductors 53 are formed.

The conductor layer 15, the outermost conductor layer 16, and the via conductors (52, 53) can be formed using a method and a material similar to those for forming the conductor layer 11 and the via conductors 51. In forming the through conductors 54, through holes that expose the electrodes 41 are formed by irradiating, for example, ultraviolet (UV) laser light from a surface of the insulating layer 26 toward the component 4. By filling the through holes with a plating film together with formation of the conductor layer 15, the through conductors 54 are formed.

After that, the solder resist 61 is formed on the conductor layer 15 and the insulating layer 26, and the solder resist 62 is formed on the outermost conductor layer 16 and insulating layer 27. Openings for exposing the connection pads (151, 152) are provided in the solder resist 61 on the conductor layer 15, and appropriate openings are also provided in the solder resist 62. The solder resists (61, 62) and the openings thereof are formed by forming a resin layer containing a photosensitive epoxy resin or polyimide resin or the like, followed by exposure and development using a mask having appropriate opening patterns. Through the above processes, the wiring substrate 100 is completed.

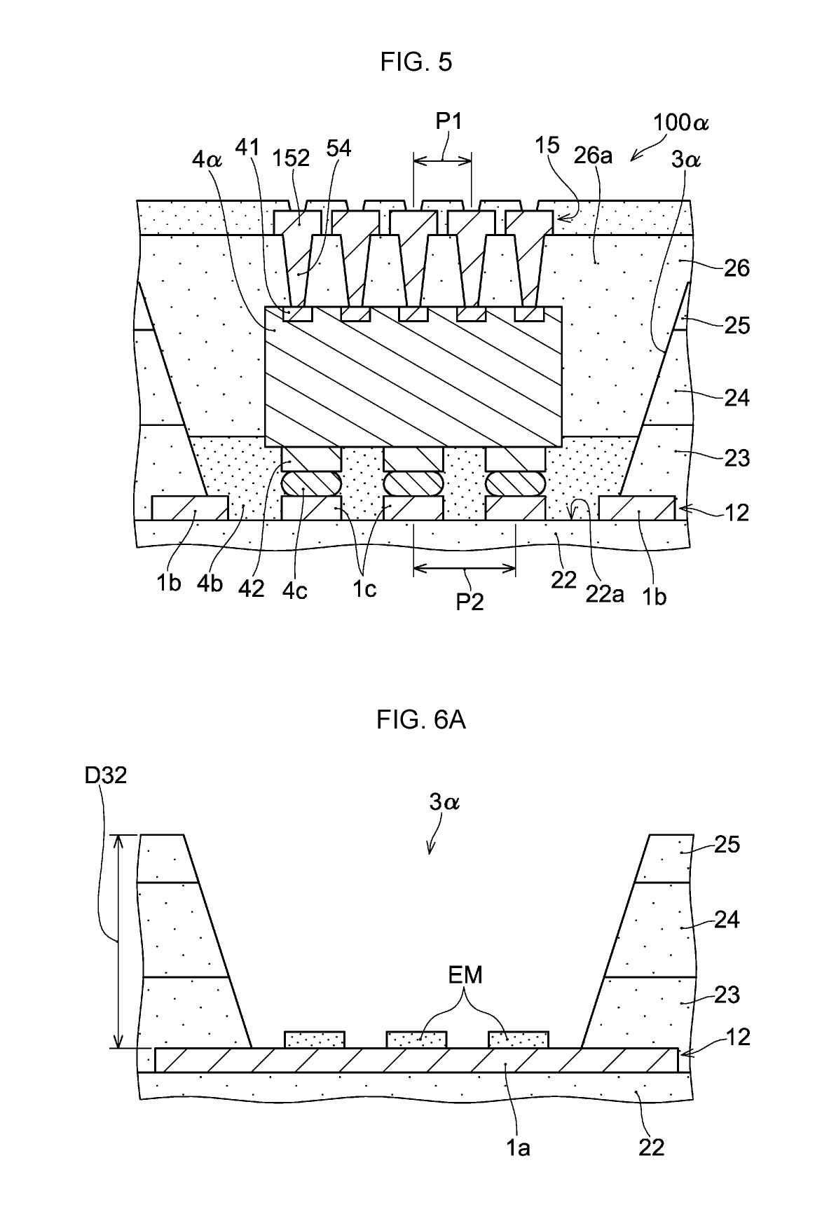

Next, a first modified example of the method for manufacturing a wiring substrate according to the embodiment is described with reference to FIGS. 5 and 6A to 6D. FIG. 5 illustrates an opening (3α) and a surrounding portion thereof in a wiring substrate (100α), which is an example of a wiring substrate manufactured using the first modified example of the manufacturing method of the embodiment. A structure of a region other than a surrounding portion of the opening (3α) illustrated in FIG. 5 in the wiring substrate (100α) may be the same as a structure of a corresponding region in the wiring substrate 100 illustrated in FIG. 1. Therefore, description of a structure of a region not illustrated in FIG. 5 is omitted, and a structure in the wiring substrate (100α) that is different from the wiring substrate 100 is mainly described.

As illustrated in FIG. 5, the opening (3α) of the wiring substrate (100α) penetrates collectively insulating layers (23, 24) that correspond to the insulating layers (23, 24) of the wiring substrate 100 of FIG. 1. A component (4α) is positioned inside the opening (3α). At a bottom surface of the opening (3α), a surface (22a) of an insulating layer 22 is exposed by formation of the opening (3α). Therefore, in the wiring substrate (100α), the insulating layer 22 is an insulating layer that is also referred to as a first insulating layer. Further, the insulating layer 23 that is directly formed on the insulating layer 22 is an insulating layer that is also referred to as a second insulating layer.

Similar to the wiring substrate 100 of FIG. 1, a conductor layer 12 is formed on the surface (22a) of the insulating layer 22 of the wiring substrate (100α), and in the wiring substrate 100, the conductor layer 12 includes the frame-shaped conductor pattern (1b). The conductor layer 12 further includes multiple component mounting pads (1c) that are exposed in the opening (3α). On surfaces of the component mounting pads (1c), a surface treatment film (not illustrated) made of, for example, any metal or organic compound or the like may be formed.

Similarly to the component 4 of FIG. 1, the component (4α) has multiple electrodes 41 on an upper surface thereof, and further has multiple electrodes 42 on a surface on an opposite side with respect to the upper surface on which the electrodes 41 are formed. The multiple electrodes 41 are formed at a pitch smaller than a pitch of the multiple electrodes 42. Although not illustrated, the electrodes 41 and the electrodes 42 may be connected, directly or indirectly via any elements, for example, by through electrodes such as through-silicon vias (TSV) that penetrate the component (4α) in a thickness direction thereof. Similarly to the component 4 of FIG. 1, the component (4α) may be any active component, passive component, or wiring member or the like.

The electrodes 42 of the component (4α) are connected to the component mounting pads (1c), for example, by a conductive bonding material (4c) made of solder or the like. Further, a body portion itself of the component (4α) is fixed to the surface (22a) of the insulating layer 22 and to a wall surface of the opening (3α) by an adhesive (4b) made of, for example, an epoxy resin or the like. A portion near the bottom surface of the opening (3α) is filled with the adhesive (4b). Therefore, a portion of the frame-shaped conductor pattern (1b) that is exposed in the opening (3α) is covered by the adhesive (4b). A gap between the component (4α) and the surface (22a) is also filled with the adhesive (4b). The adhesive (4b) may function as an underfill material for the component (4α).

In the opening (3α), a region that is not filled with the adhesive (4b) is filled with a filling resin (26a) integral with the insulating layer 26, that is, with a part of a resin material constituting the insulating layer 26. The component (4α) is covered by the filling resin (26a) integral with the insulating layer 26 and is sealed by the filling resin (26a). The insulating layer 26 also functions as a sealing layer in the wiring substrate (100α).

Similar to the wiring substrate 100 of FIG. 1, in the wiring substrate (100α) as well, multiple through conductors 54 are formed that penetrate the insulating layer 26 and connect the connection pads 152 of the conductor layer 15 to the electrodes 41 of the component (4α). In the example of FIG. 5, a pitch (P1) of the multiple through conductors 54 and the multiple connection pads 152 is smaller than a pitch (P2) of the multiple component mounting pads (1c). The pitch (P1) may be, for example, about 45 μm to 100 μm, and the pitch (P2) may be, for example, about 100 μm to 150 μm.

FIGS. 6A to 6D illustrate an example of a state of a region corresponding to the region illustrated in FIG. 5 after each process from formation of the opening (3α) to positioning of the component (4α) in the wiring substrate (100α) according to the first modified example of the manufacturing method of the embodiment. In processes before and after the processes in which the wiring substrate (100α) being manufactured reaches the states illustrated in FIGS. 6A to 6D, structural elements of the wiring substrate (100α) can be formed using methods similar to those described with reference to FIGS. 4A to 4J. Therefore, description of the processes in which those similar methods can be used is omitted.

First, as described with reference to FIGS. 4A to 4C, the core substrate 10, the insulating layers (21 to 25), the conductor layers (11, 14), as well as the five insulating layers 27 and the four conductor layers 16 are formed. In manufacturing the wiring substrate (100α), as illustrated in FIG. 6A, the conductor layer 12 is formed so as to include the conductor pad (1a). Then, the opening (3α) is formed using a method similar to the method for forming the opening 3 described with reference to FIG. 4D. The opening (3α) is formed by irradiation with laser light so as to penetrate the insulating layer 25, the insulating layer 24, and the insulating layer 23 and expose the conductor pad (1a) of the conductor layer 12. Preferably, the conductor pad (1a) is used as a laser stopper that prevents the laser light from reaching the insulating layer 22. As an example, the opening (3α) having a depth (D32) of about 100 μm to 150 μm may be formed.

After formation of the opening (3α), an etching mask (EM) is formed on a surface of the conductor pad (1a) that is exposed in the opening (3α), for example, by application and drying of a liquid resist, or by lamination of a dry film resist. The etching mask (EM) is formed, for example by photolithography, only on the surface of the conductor pad (1a) corresponding to a formation region of the component mounting pads (1c) (see FIG. 6B). Then, the conductor pad (1a) is patterned, for example, by wet etching. Specifically, a portion of the conductor pad (1a) that is exposed without being covered by the etching mask (EM) is removed. That is, an exposed portion of the conductor pad (1a) in the opening (3α) is partially removed. After patterning of the conductor pad (1a), the etching mask (EM) is removed using an appropriate stripping agent.

As illustrated in FIG. 6B, by patterning, the multiple component mounting pads (1c) individually separated are formed. In this way, in the manufacturing method of the embodiment, etching the exposed portion of the conductor pad may include forming the component mounting pads on the surface of the first insulating layer (the surface (22a) of the insulating layer 22 in FIG. 6B) by patterning the exposed portion of the conductor pad. On surfaces of the component mounting pads (1c), a surface treatment film (not illustrated) containing nickel, palladium, and/or gold or the like, or composed of an organic compound having a corrosion-inhibiting effect, may be formed by, for example, electroless plating, sputtering, spraying, or the like.

In the etching for forming the component mounting pads (1c), for a reason similar to that described with reference to FIG. 4E, a non-exposed portion of the conductor pad to be etched that is covered by the insulating layer 23 is also partially removed. As a result, a remaining portion (1aa) of the conductor pad (1a) remains covered by the insulating layer 23 at a position recessed from an inner wall surface of the insulating layer 23 exposed in the opening (3α). The remaining portion (1aa) constitutes the frame-shaped conductor pattern (1b) illustrated in FIG. 5.

Further, by etching the non-exposed portion of the conductor pad (1a), a recess 31 having a form similar to that of the recess 31 illustrated in FIG. 4E is formed in a wall surface (3a) of the opening (3α) (the inner wall surface of the insulating layer 23 exposed in the opening (3α). A surface of the remaining portion (1aa) is exposed in the recess 31. Similarly to the recess 31 illustrated in FIG. 4E, the recess 31 illustrated in FIG. 6B may be formed over the entire wall surface (3a) surrounding the opening (3α), and may be formed in a groove shape along a circumferential direction of the opening 3 in plan view. The recess 31 has a depth in a direction outward from the opening (3α) along the surface (22a) of the insulating layer 22.

Then, the inner wall surface of the insulating layer 23 is cut so as to reduce the depth of the recess 31. That is, the present modified example also includes making the depth of the recess 31 smaller than a depth (D1) immediately after formation of the recess 31. The inner wall surface of the insulating layer 23 may be cut, for example, using a method as described with reference to FIG. 4F. That is, the inner wall surface of the insulating layer 23 may be cut by irradiation with laser light (L), or may be cut using any other method, for example, by drilling or the like. Further, also in the present modified example, cutting of the inner wall surface of the insulating layer 23 may include making an opening area of the opening (3α) larger than immediately after formation of the opening (3α).

Further, as illustrated in FIG. 6B, by cutting the inner wall surfaces of the insulating layers (23 to 25) with a cutting width (length of a cutting allowance (CS)) larger than the depth (D1) of the recess 31, the recess 31 may be eliminated after irradiation with the laser light (L). Then, the remaining portion (1aa) is partially exposed from the insulating layer 23, and thus, as illustrated in FIG. 6C, a part of the remaining portion (1aa) may be exposed in the opening (3α). FIG. 6C illustrates the opening (3α) after irradiation with the laser light of FIG. 6B. Also in the present modified example, the inner wall surface of the insulating layer 23 may be cut such that the recess 31 remains with a depth smaller than the depth (D1) immediately after formation of the recess 31.

As illustrated in FIG. 6C, the component (4α) is positioned in the opening (3α). In the example of FIG. 6C, the component (4α) is positioned in the opening (3α) with the electrodes 41 facing upward. The component (4α) is positioned and placed in the opening (3α) such that the electrodes 42 provided on the surface on an opposite side with respect to the electrodes 41 overlap with the component mounting pads (1c) in plan view. The conductive bonding material (4c) made of, for example, solder or the like is provided on each of the multiple electrodes 42. Further, the component (4α) illustrated in FIG. 6C includes, on the surface on the electrode 42 side, an insulating film 43 formed on a film and composed of, for example, an epoxy resin or the like.

When placed on the component mounting pads (1c), the component (4α) is fixed in the opening (3α) by, for example, heating and pressing. That is, by pressing, the bonding material (4c) penetrates the insulating film 43 and protrudes from the insulating film 43 to come into contact with the component mounting pads (1c). Then, the bonding material (4c) is melted by heating and subsequently solidified, thereby connecting the electrodes 42 and the component mounting pads (1c). Further, the insulating film 43 softens to a liquid or paste state by heating and subsequently hardens, thereby bonding the component (4α) to the bottom surface and wall surface of the opening (3α). In this way, in the manufacturing method of the embodiment, positioning the component in the opening that penetrates the second insulating layer (the insulating layer 23 in FIG. 6C) may include connecting the electrodes provided on the component to the component mounting pads.

As a result of the heating and pressing treatment applied to the component (4α), as illustrated in FIG. 6D, the component (4α) is fixed in the opening (3α). The electrodes 42 of the component (4α) are connected to the component mounting pads (1c) via the bonding material (4c). Further, the gap between the component (4α) and the surface (22a) of the insulating layer 22 is filled with the insulating adhesive (4b) made of the insulating film 43 (see FIG. 6C) that has once softened and then hardened. Further, a portion near the bottom surface of the opening (3α) is filled with the adhesive (4b). Therefore, the remaining portion (1aa) of the conductor pad that is exposed in the opening (3α) after reducing the depth of the recess 31 (see FIG. 6B) is covered by the adhesive (4b). Since the exposed portion of the remaining portion (1aa) is covered by the insulating adhesive (4b), a short-circuit failure due to unintended contact between the remaining portion (1aa) and any conductor may be prevented. In this way, in the manufacturing method of the embodiment, positioning the component in the opening that penetrates the second insulating layer (the insulating layer 23 in FIG. 6D) may include covering the remaining portion of the conductor pad with the adhesive provided on the component.

After fixing the component (4α) in the opening (3α), the insulating layers (26, 27) are formed, the opening (3α) is filled with a part of the resin material constituting the insulating layer 26, and furthermore, the conductor layers (15, 16) as well as the solder resists (61, 62) are formed, using methods similar to those described with reference to FIGS. 4I and 4J. As a result, the wiring substrate (100α) having the opening (3α) and the mounting structure of the component (4α) as illustrated in FIG. 5 is completed.

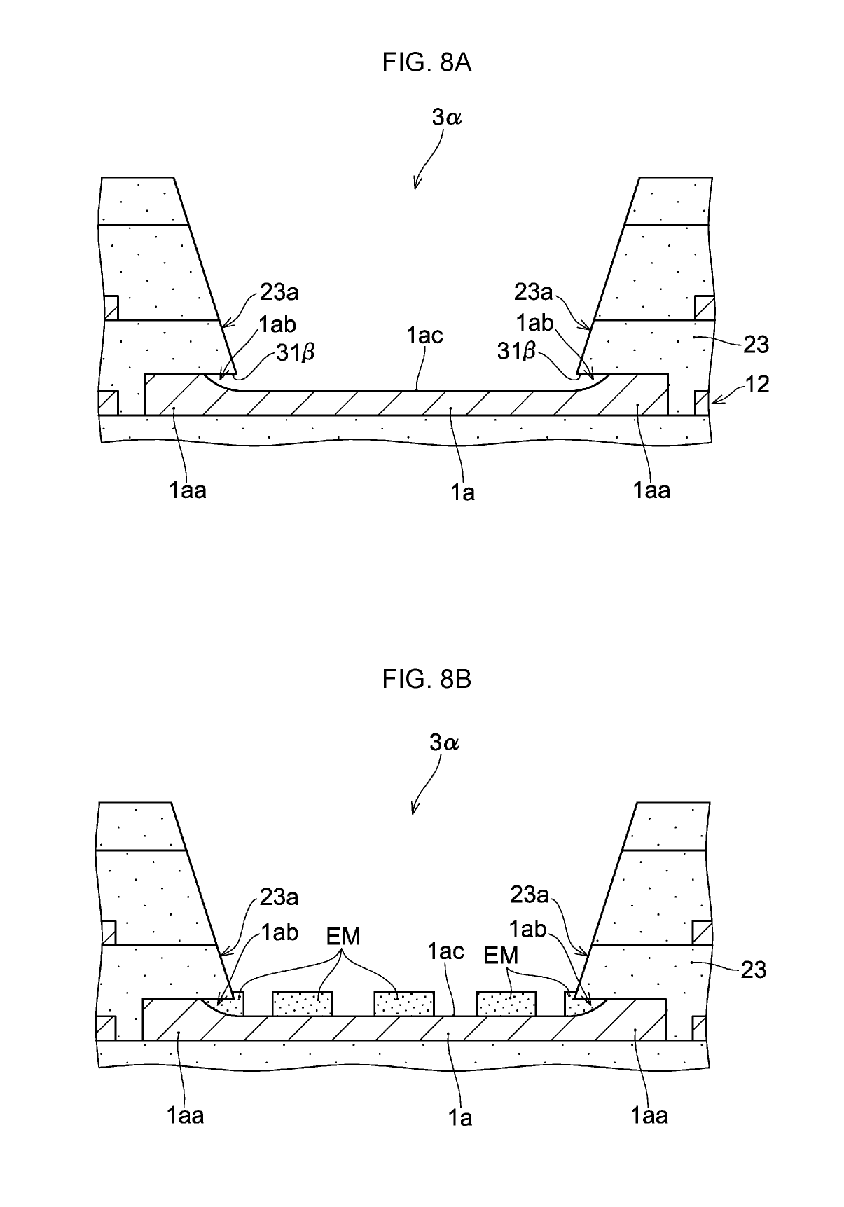

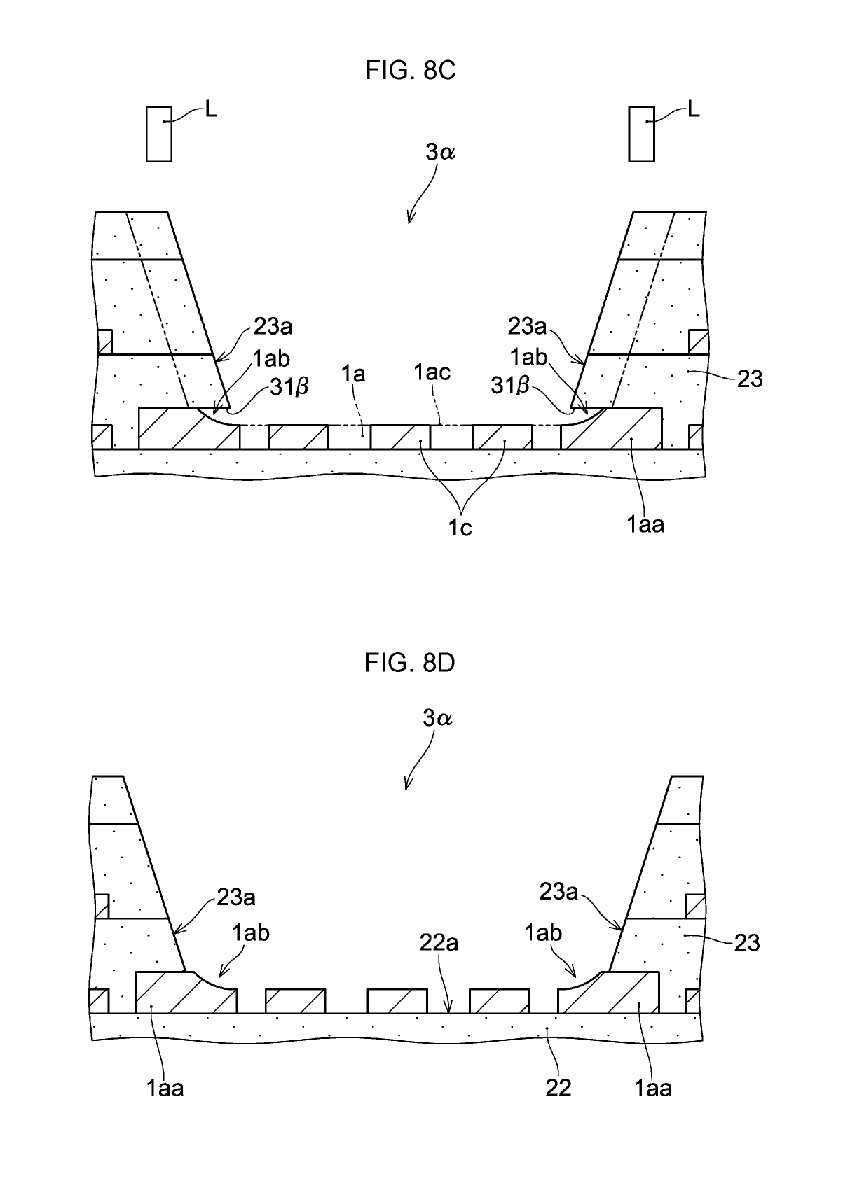

Next, a second modified example of the method for manufacturing a wiring substrate according to the embodiment is described with reference to FIGS. 7 and 8A to 8D. FIG. 7 illustrates an opening (3α) and a surrounding portion thereof in a wiring substrate (100β), which is an example of a wiring substrate manufactured using the second modified example of the manufacturing method of the embodiment. The wiring substrate (100β) differs from the wiring substrate (100α) of FIG. 5, which is an example of a wiring substrate manufactured using the first modified example of the manufacturing method of the embodiment, only in a shape of the frame-shaped conductor pattern (1b). Therefore, for structural elements other than the frame-shaped conductor pattern (1b), the same reference numeral symbols as those used in FIG. 5 are assigned or are omitted as appropriate in FIG. 7, and repeated descriptions thereof are omitted.

In the wiring substrate (100β) illustrated in FIG. 7, a thickness at an edge portion on an outer peripheral side (outer edge) of the frame-shaped conductor pattern (1b) in the opening (3α) is greater than a thickness at an end portion on an inner peripheral side (inner edge). Therefore, the frame-shaped conductor pattern (1b) has a transition portion (1ab) where its thickness changes. In the example of FIG. 7, an upper surface of the thickness transition portion (1ab) of the frame-shaped conductor pattern (1b) is constituted by a curved inclined surface that gently curves downward to connect a thick portion and a thin portion. In the present modified example, the thickness of the frame-shaped conductor pattern (1b) does not necessarily need to change gradually as in the example of FIG. 7, and may change abruptly, for example, by a process. Therefore, the transition portion (1ab) may be a stepped portion where the thickness of the frame-shaped conductor pattern (1b) changes.

In the present modified example, as in the example illustrated in FIG. 7, the thickness of the frame-shaped conductor pattern (1b) at the outer edge is larger than the thickness at the inner edge, and the frame-shaped conductor pattern (1b) has the thickness transition portion (1ab). And, the transition portion (1ab) is exposed from the insulating layer 23 and is exposed in the opening (3α). Therefore, it is thought that an exposed surface area of the frame-shaped conductor pattern (1b) in the opening (3α) is larger compared to the case where the frame-shaped conductor pattern (1b) does not have the thickness transition portion (1ab). Therefore, it is thought that a contact area between the adhesive (4b) and the frame-shaped conductor pattern (1b) is increased and the component (4α) is more firmly fixed in the opening (3α). Further, in the example of FIG. 7, since the upper surface of the transition portion (1ab) is a gently curved inclined surface, it is thought that flow of the adhesive (4b) is promoted and gaps such as voids are unlikely to occur.

FIGS. 8A to 8D illustrate an example of a state around the opening (3α) after each process from formation of the opening (3α) to formation of the component mounting pads (1c) in manufacturing the wiring substrate (100β) according to the present modified example. In processes before and after the processes in which the wiring substrate (100β) being manufactured reaches the states illustrated in FIGS. 8A to 8D, structural elements of the wiring substrate (100β) can be formed using methods similar to those described with reference to FIGS. 4A to 4J or those described with reference to FIGS. 6A to 6D. Therefore, description of the processes in which those similar methods can be used is omitted. Further, structural elements illustrated in FIGS. 8A to 8D are assigned the same reference numeral symbols as those assigned to the corresponding structural elements in FIGS. 6A to 6D, or the assignment of reference numeral symbols is omitted as appropriate.

As illustrated in FIG. 8A, also in manufacturing the wiring substrate (100β), the conductor layer 12 is formed so as to include the conductor pad (1a), using a method similar to that described with reference to FIGS. 6A to 6D. Then, also in the present modified example, an etching treatment is performed on the exposed portion and non-exposed portion of the conductor pad (1a) in the opening (3α). However, in the present modified example, in the etching of the conductor pad (1a) illustrated in FIG. 8A, etching is performed in which the conductor pad (1a) is partially removed in its thickness direction (hereinafter also referred to as “half-etching”). As illustrated in FIG. 8A, in the conductor layer 12 including the conductor pad (1a), only the thickness of the conductor pad (1a) is made greater than that of other conductor patterns. The thickness of the conductor pad (1a) may be increased using any method. For example, after formation of the entire conductor layer 12 as described with reference to FIG. 4A, the thickness of the conductor pad (1a) may be made greater than that of other conductor patterns in the conductor layer 12 by performing partial plating using a plating mask having an opening that exposes only the conductor pad (1a).

By half-etching, the thickness of the exposed portion of the conductor pad (1a) in the opening (3α) becomes smaller than before etching. Further, as described with reference to FIG. 4E, etching also proceeds on the non-exposed portion of the conductor pad (1a) that is covered by the insulating layer 23. Therefore, a part of the non-exposed portion is removed from the inner wall surface (23a) of the insulating layer 23 surrounding the opening (3α) to a portion that appropriately enters into the insulating layer 23. A portion that is not removed, as the remaining portion (1aa), remains covered by the insulating layer 23. The remaining portion (1aa) also remains at a position recessed from the wall surface (23a) of the insulating layer 23. Further, since a part of the non-exposed portion is removed, a recess (31β) is formed in the inner wall surface (23a) of the insulating layer 23. A part of a surface of the remaining portion (1aa) is exposed in the recess (31β).

A depth to which the non-exposed portion of the conductor pad (1a) is etched in the thickness direction of the conductor pad (1a) gradually becomes smaller with increasing distance from the inner wall surface (23a) of the insulating layer 23. Therefore, the thickness transition portion (1ab) having a gently curved inclined upper surface is formed in the remaining portion (1aa). As a result, a recess (1ac) having the transition portion (1ab) at an edge portion thereof, as illustrated in FIG. 8A, is formed on an upper surface of the conductor pad (1a) facing the opening (3α). In this way, in the manufacturing method of the embodiment, etching the exposed portion of the conductor pad (1a) and the surrounding non-exposed portion may include providing the recess (1ac) on a surface of the conductor pad (1a) on the opening (3α) side.

After half-etching of the conductor pad (1a), as illustrated in FIG. 8B, an etching mask (EM) is formed. The etching mask (EM) is formed on the upper surface of the conductor pad (1a) corresponding to a formation region of the component mounting pads (1c) (see FIG. 8C), for example, using a method similar to that described with reference to FIG. 6A. Further, in the present modified example, the etching mask (EM) is formed that also covers a portion of the conductor pad (1a) near the inner wall surface (23a) of the insulating layer 23 so as to cover the thickness transition portion (1ab) of the remaining portion (1aa) of the conductor pad (1a). That is, an edge potion of the recess (1ac) provided on the upper surface of the conductor pad (1a) is covered by the etching mask (EM). In this state, the conductor pad (1a) is patterned, for example, by wet etching. After patterning of the conductor pad (1a), the etching mask (EM) is removed.

As illustrated in FIG. 8C, by patterning, the multiple component mounting pads (1c) individually separated are formed. Further, in the present modified example, the edge portion of the recess (1ac), including the thickness transition portion (1ab) of the remaining portion (1aa), that was covered by the etching mask (EM) (see FIG. 8B), also remains after formation of the component mounting pads (1c). In this way, the manufacturing method of the embodiment may include, as in the present modified example, forming the component mounting pads (1c) while leaving the edge portion of the recess (1ac) by patterning the conductor pad (1a) provided with the recess (1ac). The remaining portion (1aa) including the thickness transition portion (1ab) that remains after formation of the component mounting pads (1c) constitutes the frame-shaped conductor pattern (1b) in the wiring substrate (100β) of FIG. 7.

Then, the inner wall surface (23a) of the insulating layer 23 is cut so as to reduce the depth of the recess (31β). The inner wall surface (23a) of the insulating layer 23 may be cut, for example, using a method as described with reference to FIG. 4F. That is, the inner wall surface (23a) of the insulating layer 23 may be cut by irradiation with laser light (L), or may be cut using any other method, for example, by drilling or the like. By cutting the inner wall surface (23a) of the insulating layer 23 so as to reduce the depth of the recess (31β), the recess (31β) is eliminated.

As a result, as illustrated in FIG. 8D, the edge portion of the recess (1ac) on the upper surface of the conductor pad (see FIG. 8B) is exposed from the insulating layer 23. That is, the thickness transition portion (1ab) of the remaining portion (1aa) of the conductor pad is exposed in the opening (3α). In this way, in the manufacturing method of the embodiment, cutting the inner wall surface (23a) of the insulating layer 23 exposed in the opening (3α) may include exposing the edge portion of the recess (1ac) of the conductor pad from the insulating layer 23.

After the thickness transition portion (1ab) of the remaining portion (1aa) is exposed in the opening (3α), the component (4α) (see FIG. 6D) is positioned and fixed in the opening (3α) using a method similar to that described with reference to FIGS. 6C and 6D. That is, with the adhesive (4b) (see FIG. 6D), a gap between the component (4α) and the surface (22a) of the insulating layer 22 is filled, and a portion near the bottom surface of the opening (3α) is filled. The thickness transition portion (1ab) of the remaining portion (1aa) exposed in the opening (3α) is also covered by the adhesive (4b). Since the remaining portion (1aa) has the thickness transition portion (1ab), it is thought that an adhesion area between the remaining portion (1aa) and the adhesive (4b) is larger than when the remaining portion (1aa) does not have the transition portion (1ab). Therefore, it is thought that the component (4α) is more firmly fixed in the opening (3α). Further, since the upper surface of the transition portion (1ab) is a gently curved inclined surface, it is thought that flow of the adhesive (4b) is promoted and gaps such as voids are unlikely to occur in a portion near the bottom surface of the opening (3α).

After fixing the component (4α) in the opening (3α), the insulating layers (26, 27) are formed, and the opening (3α) is filled with a part of the resin material constituting the insulating layer 26, as illustrated in FIGS. 4I and 4J, using methods similar to those described with reference to FIGS. 4I and 4J. Further, the conductor layers (15, 16) as well as the solder resists (61, 62) are formed. As a result, the wiring substrate (100β) is completed that includes the frame-shaped conductor pattern (1b) constituted by the remaining portion (1aa) of the conductor pad and having the shape illustrated in FIG. 7.

The method for manufacturing a wiring substrate according to the embodiment is not limited the method described with reference to the drawings. For example, the conductor layers may be formed using a full additive method. The insulating layers may each be formed using a resin in any form without being limited to a film-like resin. The openings (3, 3α) may penetrate only a single insulating layer. The component (4α) does not necessarily need to include a bonding material or an insulating film, and these may be supplied separately. In the method for manufacturing the wiring substrate of the embodiment, it is also possible that any process other than the processes described above is added, or some of the processes described above are omitted.

Japanese Patent Application Laid-Open Publication No. 2020-184596 describes a method for manufacturing an electronic component-embedded wiring substrate. In the manufacturing method described in Japanese Patent Application Laid-Open Publication No. 2020-184596, a first buildup insulating layer and a protective insulating layer are laminated on a solid plane layer formed in an inner-layer buildup conductor layer. A cavity that penetrates these insulating layers and exposes the plane layer at its bottom surface is formed with an opening area smaller than an area of the plane layer. Then, after the plane layer exposed in the cavity is removed by an etching treatment, a semiconductor component is placed on the bottom surface of the cavity, and the cavity is filled with resin by laminating an outer buildup insulating layer.

In the method for manufacturing an electronic component-embedded wiring board described in Japanese Patent Application Laid-Open Publication No. 2020-184596, when removing a portion of the plane layer exposed in the cavity by etching, a part of a portion of the plane layer on an outer side of the cavity is also removed. As a result, a recess (lateral extension portion) that is recessed outward from the cavity is formed in a wall surface near the bottom surface of the cavity. When a recess is formed in the wall surface of the cavity as in the manufacturing method of Japanese Patent Application Laid-Open Publication No. 2020-184596, the resin filling the cavity may be unable to enter into the recess, resulting in formation of gaps in the recess and occurrence of voids.

A method for manufacturing a wiring substrate according to an embodiment of the present invention includes: forming a conductor layer including a conductor pad on a surface of a first insulating layer; forming a second insulating layer covering the first insulating layer and the conductor layer; forming, by irradiation with laser light, an opening that penetrates the second insulating layer and partially exposes the conductor pad; etching an exposed portion of the conductor pad and a non-exposed portion surrounding the exposed portion so that a remaining portion of the conductor pad remains at a position recessed from an inner wall surface of the second insulating layer exposed in the opening; forming, in the inner wall surface, a recess that exposes a surface of the remaining portion by etching the non-exposed portion; cutting the inner wall surface so as to reduce a depth of the recess; positioning a component in the opening; and filling the opening with resin.

According to an embodiment of the present invention, it is thought that a component-embedded wiring substrate can be manufactured with good quality by suppressing occurrence of voids.

Obviously, numerous modifications and variations of the present invention are possible in light of the above teachings. It is therefore to be understood that within the scope of the appended claims, the invention may be practiced otherwise than as specifically described herein.

1. A method for manufacturing a wiring substrate, comprising:
forming a conductor layer on a surface of a first insulating layer such that the conductor layer includes a conductor pad forming a laser stopper;
forming a second insulating layer on the first insulating layer such that the second insulating layer covers the conductor layer;
forming an opening in the second insulating layer by irradiation with laser light such that the opening penetrates through the second insulating layer and partially exposes the conductor pad of the conductor layer;
etching the conductor pad of the conductor layer such that a recess is formed in an inner wall surface of the second insulating layer in the opening and exposes a surface of a remaining portion of the conductor pad at a position recessed from the inner wall surface of the second insulating layer in the opening;
cutting the inner wall surface of the second insulating layer in the opening such that a depth of the recess formed in the inner wall surface of the second insulating layer is reduced;
positioning a component in the opening formed in the second insulating layer such that the component is mounted in the opening formed in the second insulating layer; and
filling the opening formed in the second insulating layer with resin such that the resin fills the opening of the second insulating layer in which the component is mounted.

2. The method for manufacturing a wiring substrate according to claim 1, wherein the cutting the inner wall surface of the second insulating layer includes exposing the remaining portion of the conductive pad from the second insulating layer.

3. The method for manufacturing a wiring substrate according to claim 2, wherein the filling the opening formed in the second insulating layer with the resin includes covering the remaining portion of the conductive pad with the resin.

4. The method for manufacturing a wiring substrate according to claim 1, wherein the cutting the inner wall surface of the second insulating layer includes irradiating laser light around the opening formed in the second insulating layer.

5. The method for manufacturing a wiring substrate according to claim 1, wherein the etching the conductor pad includes patterning the conductor pads such that a plurality of component mounting pads is formed on a surface of the first insulating layer.

6. The method for manufacturing a wiring substrate according to claim 5, wherein the positioning the component in the opening of the second insulating layer includes connecting a plurality of electrodes on the component to the component mounting pads formed on the surface of the first insulating layer.

7. The method for manufacturing a wiring substrate according to claim 1, wherein the filling the resin in the opening of the second insulating layer includes forming a third insulating layer on the second insulating layer on an opposite side with respect to the first insulating layer such that the opening is filled with the resin derived from the third insulating layer and that the resin covers the component mounted in the opening of the second insulating layer.

8. The method for manufacturing a wiring substrate according to claim 1, wherein the etching the conductor pad includes forming a recess on a surface of the conductor pad on an opening side of the opening, and the cutting the inner wall surface of the second insulating layer includes exposing an edge portion of the recess formed on the surface of the conductor pad from the second insulating layer.

9. The method for manufacturing a wiring substrate according to claim 8, further comprising:
patterning the conductor pad having the recess formed on the surface of the conductor pad such that a plurality of component mounting pads is formed on the first insulating layer and that the edge portion of the recess formed on the surface of the conductor pad is left on the first insulating layer.

10. The method for manufacturing a wiring substrate according to claim 2, wherein the cutting the inner wall surface of the second insulating layer includes irradiating laser light around the opening formed in the second insulating layer.

11. The method for manufacturing a wiring substrate according to claim 2, wherein the etching the conductor pad includes patterning the conductor pads such that a plurality of component mounting pads is formed on a surface of the first insulating layer.

12. The method for manufacturing a wiring substrate according to claim 11, wherein the positioning the component in the opening of the second insulating layer includes connecting a plurality of electrodes on the component to the component mounting pads formed on the surface of the first insulating layer.

13. The method for manufacturing a wiring substrate according to claim 2, wherein the filling the resin in the opening of the second insulating layer includes forming a third insulating layer on the second insulating layer on an opposite side with respect to the first insulating layer such that the opening is filled with the resin derived from the third insulating layer and that the resin covers the component mounted in the opening of the second insulating layer.

14. The method for manufacturing a wiring substrate according to claim 2, wherein the etching the conductor pad includes forming a recess on a surface of the conductor pad on an opening side of the opening, and the cutting the inner wall surface of the second insulating layer includes exposing an edge portion of the recess formed on the surface of the conductor pad from the second insulating layer.

15. The method for manufacturing a wiring substrate according to claim 14, further comprising:
patterning the conductor pad having the recess formed on the surface of the conductor pad such that a plurality of component mounting pads is formed on the first insulating layer and that the edge portion of the recess formed on the surface of the conductor pad is left on the first insulating layer.

16. The method for manufacturing a wiring substrate according to claim 3, wherein the cutting the inner wall surface of the second insulating layer includes irradiating laser light around the opening formed in the second insulating layer.

17. The method for manufacturing a wiring substrate according to claim 3, wherein the etching the conductor pad includes patterning the conductor pads such that a plurality of component mounting pads is formed on a surface of the first insulating layer.

18. The method for manufacturing a wiring substrate according to claim 17, wherein the positioning the component in the opening of the second insulating layer includes connecting a plurality of electrodes on the component to the component mounting pads formed on the surface of the first insulating layer.

19. The method for manufacturing a wiring substrate according to claim 3, wherein the filling the resin in the opening of the second insulating layer includes forming a third insulating layer on the second insulating layer on an opposite side with respect to the first insulating layer such that the opening is filled with the resin derived from the third insulating layer and that the resin covers the component mounted in the opening of the second insulating layer.

20. The method for manufacturing a wiring substrate according to claim 3, wherein the etching the conductor pad includes forming a recess on a surface of the conductor pad on an opening side of the opening, and the cutting the inner wall surface of the second insulating layer includes exposing an edge portion of the recess formed on the surface of the conductor pad from the second insulating layer.
